(19) United States
(12) Patent Application Publication
(10) Pub. No.: US 2025/0331313 A1
(43) Pub. Date: Oct. 23, 2025

(54) BIFACIAL PERC SOLAR CELLS AND METHODS FOR THE PRODUCTION THEREOF

(71) Applicant: Avalon Solar Technologies Pty. Ltd., New South Wales (AU)

(72) Inventors: Matthew Bruce EDWARDS, New South Wales (AU); Alexander SLADE, New South Wales (AU); Richard YOUNG, Bath (GB)

(21) Appl. No.: 19/121,104

(22) PCT Filed: Oct. 14, 2023
(86) PCT No.: PCT/AU2023/051016

§ 371 Date: Apr. 14, 2025

(30) Foreign Application Priority Data
Oct. 14, 2022 (AU) 2022903023

(51) Int. Cl. H10F 10/14; C03C 8/22; H10F 71/00; H10F 77/30

(52) U.S. Cl. CPC H10F 10/148; C03C 8/22; H10F 71/129; H10F 77/311; C03C 2214/08

(57) ABSTRACT

The present disclosure generally relates to a fire-through aluminium paste composition to selectively fire through a passivation layer, and fired compositions thereof. In particular, the fire-through aluminium paste composition of the present disclosure comprises an aluminium component and a glass component, wherein the glass component comprises at least two glass frits. The present disclosure also relates to a processes for preparing a fire-through aluminium paste composition, and its use in the manufacture of a bifacial PERC solar cell.

### FIELD

The present disclosure generally relates to a fire-through aluminium paste composition to selectively fire through a passivation layer, and fired compositions thereof. In particular, the fire-through aluminium paste composition of the present disclosure comprises an aluminium component and a glass component, wherein the glass component comprises at least two glass frits. The present disclosure also relates to a processes for preparing a fire-through aluminium paste composition, and its use in the manufacture of a bifacial PERC solar cell.

### BACKGROUND

Solar cells are typically fabricated to include a semiconductor base/body, usually silicon, a passivating dielectric layer on or over the silicon, and a metallization structure. When light is absorbed in the semiconductor base, electrical charges are excited and move to the semiconductor surface where they can be extracted at the metallization structure for use in external circuits. The dielectric passivation layer reduces recombination of charges at the semiconductor surface, thereby improving device efficiency.

To effectively extract charges from the solar cell, the metallization structure passes through the dielectric passivation layer to contact the semiconductor underneath the dielectric passivation layer, or to contact a conductive layer underneath the dielectric passivation layer. Where contact is with the semiconductor material it may be with a conductive region of the semiconductor material such as the emitter or p-type bulk for a screen-printed passivated rear emitter contact (PERC) solar cell.

Two different techniques can be employed for the fabrication of rear localised contacts. One approach is to locally open the passivation layer followed by full area screen printing, or other patterning technologies, of aluminium paste and subsequent thermal alloying to form contacts. The other method is full area screen printing of aluminium paste on the passivation layer followed by laser firing through the dielectric layer to form the local contact at the laser openings. The laser step and the use of full area print aluminium adds cost, while the use of full area print aluminium may also lead to wafer bowing during firing that is driven by the well known difference in thermal expansions of the silicon and the metallization layers, the extent which is controlled by the composition, the relative thicknesses of the prints and the silicon substrate. Excessive bowing above a threshold can provide challenges in cell handling, module assembly and life performance as cracks or cell breakage can occur. Therefore, to reduce failure, the bowing threshold is specified to be below a value that means that solar cells need to be formed from silicon wafers above a certain thickness to reduce differential thermal expansion effects to retain flatness and thus prevent breakage during cell handling in production. Furthermore, silicon is a relatively brittle material and susceptible to cracks and even fracture, however, below a critical thickness and dimension, the silicon wafers become flexible without crack propagation. Conversely, thin and flexible cells are more susceptible to bowing for the same metallization print thicknesses that obviates cell handling in production and module assembly. The industry standards use silicon with thicknesses that suppress the influence of bowing, however, conversely, limits the industry to produce modules that are flat and rigid the generates additional costs in both production and installation. Cost of the silicon is the largest component in the bill of materials, reduction of the cost contribution by reducing silicon thickness is clearly an incentive towards reducing the overall cost of energy. The full rear aluminium print is opaque blocking light from the rear side, so that standard PERC processes are incompatible with bifaciality.

Therefore, there is a need to provide new and alternative fire-through paste compositions for bifacial PERC solar cells, negating the use of the laser, particularly those comprising an aluminium glass composite, that can facilitate aluminium metallisation on the back surface of the silicon substrate to form an Al—Si alloy and a localised back surface field.

### SUMMARY

In one aspect there is provided a fire-through aluminium paste composition to selectively fire through a passivation layer, the paste composition comprising: an aluminium component, a glass component, and a patterning vehicle; wherein the glass component comprises at least a first glass frit (A) and a second glass frit (B), wherein the first glass frit (A) is an oxidizer of silicon nitride (SiNx) or hydrogenated silicon nitride (SiNx:Hy) and forms a low viscosity liquid at a predetermined temperature (i.e. a glass transition temperature range), and the second glass frit (B) does not comprise an oxidiser of silicon nitride (SiNx) or hydrogenated silicon nitride (SiNx:Hy) and controls the volume of the low viscosity liquid and the concentration of the first glass frit (A). In this case, A and/or B can be either a crystallized, crystallizable or vitreous glass or a crystalline system.

In another aspect there is provided a process for preparing a fire-through aluminium paste composition to selectively fire through a passivation layer, comprising: (i) providing an aluminium component and a glass component, and (ii) dispersing the aluminium component and the glass component in a patterning vehicle to form the fire-through aluminium paste composition, wherein the glass component comprises at least a first glass frit (A) and a second glass frit (B), wherein the first glass frit (A) is an oxidizer of silicon nitride (SiNx) or hydrogenated silicon nitride (SiNx:Hy) and forms a low viscosity liquid at a predetermined temperature, and the second glass frit (B) does not comprise an oxidiser of silicon nitride (SiNx) or hydrogenated silicon nitride (SiNx:Hy) and controls the volume of the low viscosity liquid and the concentration of the first glass frit (A).

In another aspect there is provided a fired back contact paste adhered to a passivation layer of a bifacial PERC solar cell comprising a silicon substrate, wherein the passivation layer is fired through to contact the silicon and enable access of aluminium to silicon for the formation of an Al—Si alloy thence on cooling enables the formation of a p+ layer through the doping of Al atoms on silicon sites, wherein the fired back contact paste, prior to firing, is a fire-through paste composition comprising: an aluminium component, a glass component, and a patterning vehicle; wherein the glass component comprises at least a first glass frit (A) and a second glass frit (B), wherein the first glass frit (A) is an oxidizer of silicon nitride (SiNx) or hydrogenated silicon nitride (SiNx:Hy) and forms a low viscosity liquid at a predetermined temperature (i.e. a glass transition temperature range), and the second glass frit (B) does not comprise an oxidiser of silicon nitride (SiNx) or hydrogenated silicon nitride (SiNx:Hy) and controls the volume of the low viscosity liquid and the concentration of the first glass frit (A). The firing profile for the formation of the p+ layer is necessarily designed to be compatible with the formation of the n+ contacts whether on the opposite face for the bifacial design or same face (in the case of interdigitated rear contacted cells) otherwise, the compositional design of the n+ contact could require significant change from conventional firing processes found in the art.

In another aspect there is provided a bifacial PERC solar cell comprising a silicon substrate and a rear contact thereon, the rear contact comprising a passivation layer at least partially coated with a fired back contact paste at the rear side of the silicon substrate, wherein the back contact paste is a fire-through aluminium paste composition to selectively fire through the passivation layer, wherein, prior to firing, the fire-through aluminium paste composition, comprises, an aluminium component, a glass component, and a patterning vehicle; wherein the glass component comprises at least a first glass frit (A) and a second glass frit (B), wherein the first glass frit (A) is an oxidizer of silicon nitride (SiNx) or hydrogenated silicon nitride (SiNx:Hy) and forms a low viscosity liquid at a predetermined temperature, and the second glass frit (B) does not comprise an oxidiser of silicon nitride (SiNx) or hydrogenated silicon nitride (SiNx:Hy) and controls the volume of the low viscosity liquid and the concentration of the first glass frit (A).

In another aspect there is provided a process for preparing a bifacial PERC solar cell, comprising: providing a silicon substrate and a rear passivation layer thereon; applying a fire-through aluminium paste composition to at least partially coat the passivation layer to selectively fire through the passivation layer, the paste composition comprising an aluminium component, a glass component, and a patterning vehicle, wherein the glass component comprises at least a first glass frit (A) and a second glass frit (B), wherein the first glass frit (A) is an oxidizer of silicon nitride (SiNx) or hydrogenated silicon nitride (SiNx:Hy) and forms a low viscosity liquid at a predetermined temperature, and the second glass frit (B) does not comprise an oxidiser of silicon nitride (SiNx) or hydrogenated silicon nitride (SiNx:Hy) and controls the volume of the low viscosity liquid and the concentration of the first glass frit (A), heating the paste composition to a predetermined temperature to fire through at least a portion of the passivation layer to contact the silicon and enable access of aluminium to silicon to facilitate contact metallisation, doping of the silicon with aluminium and formation of a back surface field.

### BRIEF DESCRIPTION OF DRAWINGS

Preferred embodiments of the present disclosure will be further described and illustrated, by way of example only, with reference to the accompanying drawings in which:

FIG. 1 is a cross sectional view of a first embodiment of the cells.

FIG. 2 is a cross sectional view of a second embodiment of the cells.

FIG. 3 is a orthogonal view of a third embodiment of the cells.

FIG. 4 is a orthogonal view of a fourth embodiment of the cells.

FIG. 5 is an optical image (Olympus OLS3000 laser microscope) of one example printed cell after firing showing Al—Si alloy formation.

FIG. 6 is a graph showing the comparison of the Voc as a function of the relative frit content in the fired compact for different thickness of AlOx in the passivation stack.

FIG. 7 is a graph showing the effect of relative frit content on the Efficiency of PERC cells with different AlOx thickness in the passivation stack.

### DETAILED DESCRIPTION

The present disclosure describes the following various non-limiting examples, which relate to investigations undertaken to identify alternative and improved fire-through aluminium paste compositions and fired compositions thereof, and to any methods of making and use thereof. The present disclosure also relates to bifacial PERC solar cells and methods for the production thereof.

### General Definitions and Terms

In the following description, reference is made to the accompanying drawings which form a part hereof, and which is shown, by way of illustration, several embodiments. It is understood that other embodiments may be utilised and structural changes may be made without departing from the scope of the present disclosure.

With regards to the definitions provided herein, unless stated otherwise, or implicit from context, the defined terms and phrases include the provided meanings. In addition, unless explicitly stated otherwise, or apparent from context, the terms and phrases below do not exclude the meaning that the term or phrase has acquired by a person skilled in the relevant art. The definitions are provided to aid in describing particular embodiments, and are not intended to limit the claimed invention, because the scope of the invention is limited only by the claims. Furthermore, unless otherwise required by context, singular terms shall include pluralities and plural terms shall include the singular.

All publications discussed and/or referenced herein are incorporated herein in their entirety.

Throughout this disclosure, unless specifically stated otherwise or the context requires otherwise, reference to a single step, composition of matter, group of steps or group of compositions of matter shall be taken to encompass one and a plurality (i.e., one or more) of those steps, compositions of matter, groups of steps or groups of compositions of matter. Thus, as used herein, the singular forms “a”, “an” and “the” include plural aspects unless the context clearly dictates otherwise. For example, reference to “a” includes a single as well as two or more; reference to “an” includes a single as well as two or more; reference to “the” includes a single as well as two or more and so forth.

Those skilled in the art will appreciate that the disclosure herein is susceptible to variations and modifications other than those specifically described. It is to be understood that the disclosure includes all such variations and modifications. The disclosure also includes all of the examples, steps, features, methods, compositions, coatings, processes, and coated substrates, referred to or indicated in this specification, individually or collectively, and any and all combinations or any two or more of said steps or features.

The term “and/or”, e.g., “X and/or Y” shall be understood to mean either “X and Y” or “X or Y” and shall be taken to provide explicit support for both meanings or for either meaning.

Unless otherwise indicated, the terms “first,” “second,” etc. are used herein merely as labels, and are not intended to impose ordinal, positional, or hierarchical requirements on the items to which these terms refer. Moreover, reference to a “second” item does not require or preclude the existence of lower-numbered item (e.g., a “first” item) and/or a higher-numbered item (e.g., a “third” item).

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example and without limitation, two of item A, one of item B, and ten of item C; four of item B and seven of item C; or some other suitable combination.

It is to be appreciated that certain features that are, for clarity, described herein in the context of separate embodiments, may also be provided in combination in a single embodiment. Conversely, various features that are, for brevity, described in the context of a single embodiment, may also be provided separately or in any sub-combination.

Throughout the present specification, various aspects and components of the invention can be presented in a range format. The range format is included for convenience and should not be interpreted as an inflexible limitation on the scope of the invention. Accordingly, the description of a range should be considered to have specifically disclosed all the possible sub-ranges as well as individual numerical values within that range, unless specifically indicated. For example, description of a range such as from 1 to 5 should be considered to have specifically disclosed sub-ranges such as from 1 to 3, from 1 to 4, from 1 to 5, from 2 to 4, from 2 to 5, from 3 to 5 etc., as well as individual and partial numbers within the recited range, for example, 1, 2, 3, 4, 5, 5.5 and 6, unless where integers are required or implicit from context. This applies regardless of the breadth of the disclosed range. Where specific values are required, these will be indicated in the specification.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

Throughout this specification, the term “consisting essentially of” is intended to exclude elements which would materially affect the properties of the claimed composition.

The terms “comprising”, “comprise” and “comprises” herein are intended to be optionally substitutable with the terms “consisting essentially of”, “consist essentially of”, “consists essentially of”, “consisting of”, “consist of” and “consists of”, respectively, in every instance.

Herein the term “about” encompasses a 10% tolerance in any value or values connected to the term.

Herein the term “weight %” may be abbreviated to as “wt %”.

Throughout this specification, the term “AlOx” is intended to include non-stoichiometric Al₂O₃ (oxygen deficient).

### Fire-Through Aluminium Paste Composition

Conventional PERC aluminium pastes are designed for architectures where the dielectric is opened to access the silicon surface, for example commonly by laser etching or by chemical etching, such that when the aluminium is fired, Al—Si alloying occurs with this silicon surface but does not fire through the dielectric surrounding the openings. In contrast, the present disclosure provides an aluminium paste that can fire directly through a rear dielectric passivation layer, so the laser openings are not required. It has been found that the contact can be preferred at the thin edge of the printed and fired aluminium-glass composite (paste) because the reaction chemistry changes from a beneficial oxidation reaction of the SiNx to a reductive reaction when the print thickness is above a critical value that disables or slows down the etch rate of the passivation layer obviating etch through. Therefore, increasing the fractal length of the print boundaries may improve Voc. It has been surprisingly found that the aluminium paste composition described herein provides one or more advantages including lower cost, enables thinner wafers, enables larger format wafers, bifaciality and the potential for flexible solar cells/modules which can be realised for emerging markets such as building integrated PV and solar electric vehicles.

The present disclosure relates to an aluminium paste that can fire directly through the rear dielectric passivation layer on a PERC cell, negating the use of the laser. The aluminium can be printed in local regions, with the resulting contacts interconnected using multiple busbar interconnection. The resulting solar cell advantageously has PERC performance, can be bifacial and shows little to no bow. Therefore, the solar cell can be made from a thin silicon wafer (e.g. as thin as 90 micron). In one embodiment the thickness of the silicon wafer may be less than about 90 micron. It will be appreciated that large area wafers, for example, up to 210 mm are also enabled, since bowing of the wafers is no longer a limiting factor. The solar cell described herein may also be cheaper since the laser processing step is removed, the amount of aluminium is a fraction of that required for a full-area print, and the silicon wafer can be thinner with potentially more wafers produced from an ingot. Furthermore, production yields can be increased as losses due to brittle fracture of the thicker wafers are reduced thereby reducing production cost. The solar cells can also be made flexible, shaped and encapsulated with flexible module materials to create a flexible or curved module, useful for emerging markets such as building integration and solar electric vehicles with curved surfaces. Implicitly, the modules will weigh less as significant weight is associated with the use of thicker glass and stronger frames to stabilize the module otherwise there is a risk again of brittle fracture of the cells in the module under stress. The technology also represents an easier retrofit of traditional screen print lines to achieve PERC performance as there is no change in firing equipment and employs low technology printing processes without lasers.

It will be appreciated that the localised contact is between silicon and aluminium, where the intent is to dope silicon with aluminium to form an enhanced p+ semiconductor and create an ohmic contact between the doped region and the aluminium metal contact. Conventionally, the formation of the p+ semiconductor is enabled either by forming a Al—Si alloy above the liquidus and cooling the melt using an appropriate high temperature firing process or by using a high energy source such as a laser. Advantageously, the present disclosure relies on using a firing process, as described in more detail below.

In relation to the composition of the surface layer, i.e., the passivation layer, the contact may only be enabled in a localised format when the surface structure employs the use of a layer of silicon nitride (or the dominant stoichiometry is Si₃N₄ with hydrogen either occluded in the lattice or incorporated chemically as a hydride, imide or amide in solid solution, referred to as SiNx:Hy or abbreviated to SiNx) which can be a single layer or a part of a multilayer of other metal or metal oxides of thickness ranges described herein. Conventionally, SiNx is called a capping layer for the passivation stack. The multilayer oxide design is optimized for passivation of the surface and enhance the open circuit voltage, and hence known as the passivation stack.

The multilayer stacks are deployed to improve passivation and enhance the open circuit voltage by reducing minority carrier recombination at the rear surface. Conventionally, these passivation stacks are constructed of SiNx-AlOx-SiOx or SiNx-AlOx, or other combinations known in the literature. The AlOx can be formed by atomic layer deposition (ALD) or by chemical vapour deposition (CVD). In some embodiments, the silicon nitride can be stoichiometric or can have hydrogen included in the composition (as an imide or amide) or occluded in the lattice. It will be appreciated that the silicon nitride layer is of nominally uniform thickness and coherent across the surface of the semiconductor. In some embodiments, the silicon surface can be planar or textured. It will be understood that the thickness of the silicon nitride layer is defined by the reaction stoichiometry.

In some embodiments of the present disclosure there is provided a fire-through aluminium paste composition to selectively fire through a passivation layer. The paste composition may comprise an aluminium component, a glass component, and a patterning vehicle. In other embodiments, the paste composition may comprise or consist of an aluminium component, a glass component, a patterning vehicle, optional silver particles or other silver source, and optional additives.

In some embodiments, the aluminium component may be present in an amount of between about 40 wt. % to about 85 wt. % based on the total weight of the paste composition, the glass component may be present in an amount of between about 0.1 wt. % to about 20 wt. % based on the total weight of the paste composition, and the patterning vehicle may be present in an amount of between about 5 wt. % to about 50 wt. % based on the total weight of the paste composition. In some embodiments, the paste composition may further comprise silver particles, wherein the silver particles may be present in an amount of less than about 0.5 wt. % when the aluminium content is present in an amount of less than about 80 wt. % based on the total weight of the paste composition.

In some embodiments, the viscosity of the paste composition may be in the range of between about 5 to about 200 Pa·s. In some embodiments, the viscosity (in Pa·s) of the paste composition may be at least about 5, 10, 15, 20, 25, 30, 35, 40, 45, 50, 55, 60, 65, 70, 75, 80, 85, 90, 95, 100, 110, 120, 130, 140, 150, 160, 170, 180, 190 or 200. In some embodiments, the viscosity (in Pa·s) of the paste composition may be less than about 200, 190, 180, 170, 160, 150, 140, 130, 120, 110, 100, 95, 90, 85, 80, 70, 60, 50, 40, 30, 20, 10 or 5. Combinations of any two or more of these upper and/or lower viscosity values are also possible. All viscosity values recited herein may be at a given shear rate. In embodiments, the shear rate may be that as used in any accepted standard testing approach in the art.

In some embodiments, the shear rate of the paste composition set to monitor design target viscosity is typically about 4 sec⁻¹.

In some embodiments, the thickness (in μm) of the paste composition deposited layer may be in a range between about 1 to about 40. In some embodiments, the thickness (in μm) of the paste composition deposited layer may be at least about 1, 5, 10, 15, 20, 25, 30, 35, or 40. In some embodiments, the thickness (in μm) of the paste composition deposited layer may be less than about 40, 30, 20, 10, 5, or 1. Combinations of any two or more of these upper and/or lower values are also possible. It will be understood that one or more advantages of the present disclosure according to at least some embodiments or examples as described herein is the physical thickness of the paste composition, and subsequently the thickness of the fired paste composition. For example, at the appropriate temperature, thin porous layers of the paste composition and/or the fired paste composition will have interconnected porosity that will facilitate the flow of oxygen through to the SiNx surface and evolved nitrogen reaction products thereby maintaining the etching reaction as shown below in eq. 1. Above a threshold thickness, the interconnected porosity may be compromised or the oxidation of aluminium metal at temperature that preferentially consumes the available oxygen, will switch the reaction mode to that shown in eq. 2 below. As such, the reaction mode in the thin areas or at the edge will be different to the reaction mode in the thick areas of the paste composition once deposited. Using the chemical reactions referred to in eq. 1 and eq. 2, the degree of penetration through the SiNx (passivation) layer (or stack) can be managed. When the reaction conditions noted in eq. 2 is reached, the passivation functionality of the stack is sustained where the thickness of the SiNx is managed.

### Aluminium Component

In some embodiments, the major metal component of the fire-through paste is aluminium. Aluminium is used because it forms a low contact resistance p+/p surface on n-type silicon and provides a Back Surface Field (BSF) for enhancing solar cell performance. In some embodiments, the aluminium component may comprise aluminium particles that by their nature have nano scale thick layer of oxide, nitride, carbide or mixture depending on their method of manufacture.

In some embodiments, the aluminium particles may be any morphology, for example may take the form of flakes, fibres, agglomerates, colloids, nodules, granules, powders, spheres, amorphous, pulverized materials or the like, as well as combinations thereof. For example, the aluminium particles are spherical, flaked, colloidal, amorphous, or combinations thereof. The aluminium particles may have any desired shape including, but not limited to, cubic, rod like, polyhedral, spherical or semi-spherical, nodular, rounded or semi-rounded, angular, irregular, and so forth. In one embodiment, the aluminium particles may have an aspect ratio (i.e. the ratio of a length to a width, where the length and width are measured perpendicular to one another, and the length refers to the longest linearly measured dimension) of 1.0 to 10.0, 1.0 to 5.0, or 1.0 to 2.0. In one embodiment, the aluminium particles may have an aspect ratio of about 1.0 to 2.0, for example about 1.0, 1.1, 1.2, 1.3, 1.4, 1.5, 1.6, 1.7, 1.8, 1.9, or 2.0. For example, the morphology can be uniform spheres or nodular.

The mean average aluminium particle size may be in a range between about 1 μm to about 20 μm. For example, the mean average aluminium particle size may be in a range between about 4 μm to about 8 μm. In some embodiments, the particle size (in μm) of the aluminium particles may be at least about 1, 2, 3, 4, 5, 6, 7, 8, 9, 10, 11, 12, 13, 14, 15, 16, 17, 18, 19 or 20. In some embodiments, the particle size (in μm) of the aluminium particles may be less than about 20, 19, 18, 17, 16, 15, 14, 13, 12, 11, 10, 9, 8, 7, 6, 5, 4, 3, 2 or 1. Combinations of any two or more of these upper and/or lower particle sizes are also possible. The particle size is taken to be the longest cross-sectional diameter across an aluminium particle. For non-spherical aluminium particles, the particle size is taken to be the distance corresponding to the longest cross-section dimension across the particle.

The particle size can be measured by any standard method, for example laser diffraction, electron microscopy (e.g. TEM or SEM), X-ray diffraction (e.g. Scherrer equation), or dynamic light scattering. In one embodiment, the particle size can be measured using laser diffraction according to industry standard ISO 13320:2020.

In some embodiments, the aluminium component comprises an Al—Si alloy, an Al—Si eutectic alloy, an Al—B alloy, or combinations thereof. For example, as a p+ contact, the metal contains Al or Al—Si or Al—B alloys, or combinations thereof.

### Glass Component

The present disclosure requires a glass component dispersed with the aluminium component in a patterning vehicle. In some embodiments, the glass component may comprise at least a first glass frit (A) and a second glass frit (B), wherein the first glass frit (A) is an oxidizer of silicon nitride (SiNx) or hydrogenated silicon nitride (SiNx:Hy) and forms a low viscosity liquid at a predetermined temperature, and the second glass frit (B) does not comprise an oxidiser of silicon nitride (SiNx) or hydrogenated silicon nitride (SiNx:Hy) and controls the volume of the low viscosity liquid and the concentration of the first glass frit (A).

One or more advantages of the present disclosure according to at least some embodiments or examples as described herein is that the invention is facilitated by the use of an inorganic component that chemically reacts with silicon nitride to form nitrogen (that is evolved) as shown in more detail below. These elements may be selected from metal oxides (or halides) that act as oxidisers of silicon nitride. In some embodiments, this inorganic component is the chemically active ingredient in the paste composition. For example, the inorganic component is glass frit (A). In some embodiments, glass frit (A) is selected from the group consisting of Pb based glass, Bi based glass, Bi—Zn based glass, Bi—Zn—B based glass, Te based glass, Bi—Te based glass, V based glass, and combinations thereof. In some embodiments, glass frit (A) may be part of an inorganic mixture of oxides that forms a discrete melt at a predetermined temperature or as a glass that softens over a range of temperatures to provide a low viscosity liquid medium. It will be appreciated that the melt or liquid system may enable surfaces and interfaces to be wetted, for example, where the silicon nitride is wetted, above a threshold temperature, and as such the reaction will proceed at a rate that is significantly higher than a solid state chemical reaction.

In some embodiments, glass frit (B) may be present in the glass component. Glass frit (B) may be an oxide or a silicaceous glass that has known elements that do not react with silicon nitride. The role of this glass frit (B) is to advantageously control the volume of molten inorganic glass and the concentration of the active component.

In some embodiments, glass frit (A) may react (i.e., chemically) with the silicon nitride either in air or an aerobic condition and etch the silicon nitride surface. The reaction pathway, stoichiometry and reaction products can be determined by the partial pressure of oxygen. The reaction products for a system that has moderate or high partial pressures of oxygen will lead to the formation of vitreous metal silicates and evolved nitrogen. For example, using PbO as a component in the glass component, the chemical reaction is:

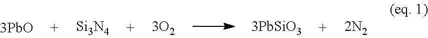

As the partial pressure of oxygen decreases, the reaction and reaction products will transition towards the chemical reaction and doubles the molar consumption of the reactant PbO. In this example, the reaction would terminate as the reactant has been consumed:

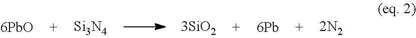

In examples comprising aluminium, above the melting point of aluminium (i.e., 680° C.) or if there is an Al—Si liquidus present, the aluminium liquid surface will oxidize consuming available oxygen thereby further reducing the partial pressure of oxygen pushing the reaction mode towards that shown in eq. 2.

In some embodiments, the ratio between the aluminium component and the first glass frit (A) is preferred to be minimized. For example, the relative frit content between the aluminium component and the first glass frit (A) may be between about 0.25% and 5% for a 50:50 blend of glass frit A and glass frit B.

In some embodiments, the glass frit (A) can be a mixture of oxides (or halides) or glasses that are composed of a glass system that chemically reacts with silicon nitride (active) and another oxide or glass admixture that acts as a diluent and does not chemically react with silicon nitride (inactive). In some embodiments, glass frit (B) may dissolve any other oxide. It will be understood that this glass system can be used as a fire through system and be selectively removed using an aqueous based chemistry for subsequent contacting processes. It will be appreciated that glass frit (B) may dissolve alumina (AlOx) contained in the passivation stack.

In some embodiments, the total amount of the glass component present in the paste composition may be in an amount between about 0.05 wt % to about 25 wt % based on the total weight of the paste composition. In some embodiments, the amount of the glass component (in wt. %) may be at least about 0.05, 0.1, 0.2, 0.4, 0.8, 1, 2, 4, 8, 10, 15, 20, or 25. In some embodiments, the amount of the glass component (in wt. %) may be less than about 25, 20, 15, 10, 8, 4, 2, 1, 0.8, 0.4, 0.2, 0.1, or 0.05. Combinations of any two or more of these upper and/or lower amounts are also possible. In some embodiments or examples, the solids content of the glass component present in the paste composition may be in the range of about 0.5% to about 20% by weight. In some embodiments, the solids content of the glass component in the paste composition may be at least about 0.5, 0.8, 1, 2, 4, 8, 10, 15, or 20% by weight. In some embodiments, the solids content of the glass component in the paste composition may be less than about 20, 15, 10, 8, 4, 2, 1, 0.8, or 0.5. Combinations of any two or more of these upper and/or lower amounts are also possible. One or more advantages of the present disclosure according to at least some embodiments or examples as described herein is provide a minimal glass content in the system in order to reduce any degradation of the passivation stack while still enabling contact with the silicon.

In some embodiments, the D₅₀ particle size of the glass component may be about 0.1 microns to about 20 microns. In some embodiments, the D₅₀ particle size of the glass component (in microns) may be at least about 0.1, 0.2, 0.4, 0.8, 1, 2, 4, 8, 10, 15, or 20. In some embodiments, the D₅₀ particle size of the glass component (in microns) may be less than about 20, 15, 10, 8, 4, 2, 1, 0.8, 0.4, 0.2 or 0.1. Combinations of any two or more of these upper and/or lower particle sizes are also possible. For screen printing paste compositions, particle size of the components must be limited in order to facilitate the particles to pass through the screens and prevent blockage of the screen mesh, the upper limit is determined by the area mesh count and open area.

### Patterning Vehicle

The pastes herein may include a patterning vehicle which is typically a solution of a resin or resins dissolved in a solvent or solvents and, frequently, a solvent solution containing both resin, a thixotropy or shear thinning modifier and a surfactant (dispersant and stabiliser). The glass frits, A and B, as described herein, can be combined with the patterning vehicle to form a printable paste composition. The patterning vehicle can be selected on the basis of its end use application. In one embodiment, the patterning vehicle adequately suspends the particulates and burn off easily upon firing of the paste on the silicon substrate. Patterning vehicles are typically organic. Examples of solvents used to make patterning vehicles include alkyl ester alcohols, terpineols, and dialkyl glycol ethers, pine oils, vegetable oils, mineral oils, low molecular weight petroleum fractions, and the like. In another embodiment, surfactants and/or other film forming modifiers can also be included.

The amount and type of patterning vehicles utilized are determined mainly by the final desired formulation viscosity, rheology, fineness of grind of the paste, substrate wettability and the desired wet print thickness. In one embodiment, the paste includes about 1 wt. % to about 50 wt. % of the patterning vehicle. In another embodiment, the paste includes about 1 wt. % to about 10 wt. % of the patterning vehicle.

The patterning vehicle typically includes (a) up to 80 wt. % organic solvent; (b) up to about 15 wt. % of a resin; (c) up to about 4 wt % of a thixotropic agent; and (d) up to about 1.5 wt. % of a wetting agent. The use of more than one solvent, resin, thixotrope, and/or wetting agent is also envisioned. Ethyl cellulose is a commonly used resin. However, resins such as ethyl hydroxyethyl cellulose, wood rosin, mixtures of ethyl cellulose and phenolic resins, polymethacrylates of lower alcohols and the monobutyl ether of ethylene glycol monoacetate can also be used. Solvents having boiling points (1 atm) from about 130° C. to about 350° C. are suitable. Widely used solvents include terpenes such as alpha- or beta-terpineol or higher boiling alcohols such as Dowanol® (diethylene glycol monoethyl ether), or mixtures thereof with other solvents such as butyl Carbitol® (diethylene glycol monobutyl ether); dibutyl Carbitol® (diethylene glycol dibutyl ether), butyl Carbitol® acetate (diethylene glycol monobutyl ether acetate), hexylene glycol, Texanol® (2,2,4-trimethyl-1,3-pentanediol monoisobutyrate), as well as other alcohol esters, kerosene.

Various combinations of these and other solvents can be formulated to obtain the desired viscosity and volatility requirements for each application. Other dispersants, surfactants and rheology modifiers, which are commonly used in thick film paste formulations, can be included. Commercial examples of such products include those sold under any of the following trademarks: Texanol® (Eastman Chemical Company, Kingsport, TN); Dowanol® and Carbitol® (Dow Chemical Co., Midland, MI); Triton® (Union Carbide Division of Dow Chemical Co., Midland, MI), Thixatrol® (Elementis Company, Hightstown NJ), and Diffusol® (Transene Co. Inc., Danvers, MA); Akzo Nobel's Doumeen® TDO (tallowpropylene diamine dioleate) and DisperBYK® 110 or 111 from Byk Chemie GmbH. Disperbyk 110 is a solution of a copolymer with acidic groups having an acid value of 53 g KOH/g, density of 1.03 at 20° C. and a flash point of 42° C. Disperbyk 111 is a copolymer with acidic groups having an acid value of 19 mg KOH/g, a density of 1.16 and a flash point over 100° C. A patterning vehicle including oleic acids, DisperBYK 111 and Duomeen TDO is preferred.

Among commonly used organic thixotropic agents is hydrogenated castor oil and derivatives thereof. A thixotrope is not always necessary because the solvent coupled with the shear thinning inherent in any suspension can alone be suitable in this regard. Furthermore, wetting agents can be employed such as fatty acid esters, e.g., N-tallow-1,3-diaminopropane dioleate; N-tallow trimethylene diamine diacetate; N-coco trimethylene diamine, beta diamines; N-oleyl trimethylene diamine; N-tallow trimethylene diamine; N-tallow trimethylene diamine dioleate, and combinations thereof.

### Silver Particles

In some embodiments, the paste composition may further comprise silver particles or other silver source. One or more advantages of the present disclosure according to at least some embodiments or examples as described herein is that the addition of silver to the paste composition may improve the contact resistance between the Al and p+ Silicon.

In one embodiment, the silver particle may be any morphology, for example may take the form of flakes, fibres, agglomerates, granules, powders, spheres, pulverized materials or the like, as well as combinations thereof. The silver particles may have any desired shape including, but not limited to, cubic, rod like, polyhedral, spherical or semi-spherical, rounded or semi-rounded, angular, irregular, and so forth. In one embodiment, the silver particles may have an aspect ratio (i.e. the ratio of a length to a width, where the length and width are measured perpendicular to one another, and the length refers to the longest linearly measured dimension) of 1.0 to 10.0, 1.0 to 5.0, or 1.0 to 2.0. In one embodiment, the silver particle may have an aspect ratio of about 1.0 to 2.0, for example about 1.0, 1.1, 1.2, 1.3, 1.4, 1.5, 1.6, 1.7, 1.8, 1.9, or 2.0. In another embodiment, the silver can be in an organometallic form such as silver nanodecoanoates or similar.

In some embodiments, the mean average silver particle size may be in a range between about 0.03 μm to about 5 μm. In some embodiments, the silver particle has a mean average particle size (in μm) of at least about 0.03, 0.05, 0.1, 0.3, 0.5, 0.7, 1, 1.5, 2, 2.5, 3, 3.5, 4 or 5. In some embodiments, the silver particle has a particle size (in μm) of less than about 5, 4, 3.5, 3, 2.5, 2, 1.5, 1, 0.7, 0.5, 0.3, 0.1, 0.05, 0.03. Combinations of any two or more of these upper and/or lower particle sizes are also possible. The particle size is taken to be the longest cross-sectional diameter across a silver particle. For non-spherical silver particles, the particle size is taken to be the distance corresponding to the longest cross-section dimension across the particle. The size of the silver particles can be measured by electron microscopy (e.g. TEM or SEM) or X-ray diffraction (e.g. Scherrer analysis of one or more diffraction peaks) or a laser particle sizer.

In some embodiments, the total amount of silver (in % w/w based on the total weight of paste composition) is at least 0.01, 0.02, 0.03, 0.04, 0.05, 0.06, 0.07, 0.08, 0.09, 0.1, 0.2, 0.3, 0.4 or 0.5. In some embodiments, the total amount of silver (in % w/w based on the total weight of the paste composition) is less than about 0.5, 0.45, 0.4, 0.35, 0.3, 0.25, 0.2, 0.15, 0.1, 0.09, 0.08, 0.06, 0.05, 0.04, 0.03, 0.02 or 0.01. Combinations of any two or more of these upper and/or lower amounts are also possible. In some embodiments, the total amount of silver (in % w/w based on the total weight of the paste composition) is less than about 0.5, preferably less than about 0.2.

### Optional Additives

In some embodiments, the paste may comprise an optional additive.

In some embodiments or examples, the paste may contain functional organometallic compounds that enhance the localised oxidation of the SiNx.

Other functional or inorganic additives can also be added to the paste to the extent of between about 0.1 wt. % to about 30 wt. %, preferably about 0.1 wt. % to about 10 wt. %, alternately from about 2 wt. % to about 25 wt. % and more preferably about 5 wt. % to about 20 wt. % based on the weight of the paste prior to firing. Other additives such as fine silicon, silica, silicon, or combinations thereof can be added to control the reactivity of the aluminium with silicon.

A mixture of (a) glasses or (b) crystalline additives and glasses or (c) one or more crystalline additives can be used to formulate a glass component in the desired compositional range. The goal is to improve the solar cell electrical performance by enhancing the removal of SiNx, AlOx and SiO₂, if present. For example, second-phase crystalline ceramic materials such as Bi₂O₃, V₂O₅, WO₃, TeO, TeO₂, and reaction products thereof and combinations thereof can be added to the glass component to adjust contact properties.

### Fired Paste Composition

The present disclosure also provides a fired back contact paste adhered to a passivation layer of a bifacial PERC solar cell comprising a silicon substrate. In some embodiments, the passivation layer may be fired through to contact the silicon and enable access of aluminium to silicon for the formation of an Al—Si alloy as the pathway to a p+ doped silicon layer. It will be appreciated that the fired back contact paste, prior to firing, is a fire-through paste composition, as described herein, and may comprise an aluminium component, a glass component, and a patterning vehicle. In some embodiments, the paste composition, as described herein, may comprise or consist of an aluminium component, a glass component, a patterning vehicle, optional silver particles or other silver source, and optional additives. The aluminium component, glass component, patterning vehicle, optional silver particles or other silver source, and optional additives may be selected from any one or more of the embodiments or examples as described herein.

In some embodiments, the Al—Si alloy formation may be localised at the edge of the print while underneath the pattern, the passivation layer function is maintained maximising the open circuit voltage. In some embodiments, the localised area may be controlled by the thickness and/or porosity of the fired back contact paste layer. In one embodiment, at least a portion of the thickness of the fired back contact paste layer thickness may be less than about 10 μm to form a localised back surface field. In another embodiment, at least a portion of the thickness of the fired back contact paste layer may be greater than about 10 μm to provide areas that do not penetrate the passivation layer through to the silicon substrate.

In some embodiments, the surface area density of the fired back contact paste layer may be 0.8 mg/cm² to 5.5 mg/cm² where the area density at the edge being an important determining factor in functionality that is driven by the partial pressure of oxygen threshold for the reaction mechanism.

### A Process for Preparing a Fire-Through Aluminium Paste Composition

The present disclosure also relates to a process for preparing a fire-through aluminium paste composition to selectively fire through a passivation layer. The process comprises: (i) providing an aluminium component and a glass component, and (ii) dispersing the aluminium component and the glass component in a patterning vehicle to form the fire-through aluminium paste composition, wherein the glass component comprises at least a first glass frit (A) and a second glass frit (B), wherein the first glass frit (A) is an oxidizer of silicon nitride (SiNₓ) or hydrogenated silicon nitride (SiNₓ:H_{y}) and forms a low viscosity liquid at a predetermined temperature, and the second glass frit (B) does not comprise an oxidiser of silicon nitride (SiNₓ) or hydrogenated silicon nitride (SiNₓ:H_{y}) and controls the volume of the low viscosity liquid and the concentration of the first glass frit (A).

In some embodiments, the process may further comprise dispersing silver particles or an organometallic silver compound (that form silver particles during pyrolysis) in the patterning vehicle. In some embodiments, the silver can be in an organometallic form such as silver nanodecoanoates or similar. In other embodiments, the silver can be in the form of silver particles, as described herein. In some embodiments, the process may further comprise one or more additives dispersed in the printing vehicle. In some embodiments, the paste composition may comprise or consist of dispersing an aluminium content, a glass component, optional silver particles or other silver source, and optional additives in the patterning vehicle. The aluminium component, glass component, patterning vehicle, optional silver particles or other silver source, and optional additives may be selected from any one or more of the embodiments or examples as described herein.

The mean average aluminium particle size may be in a range between about 1 μm to about 20 μm. For example, the mean average aluminium particle size may be in a range between about 4 μm to about 8 μm. In some embodiments, the particle size (in μm) of the aluminium particles may be at least about 1, 2, 3, 4, 5, 6, 7, 8, 9, 10, 11, 12, 13, 14, 15, 16, 17, 18, 19 or 20. In some embodiments, the particle size (in μm) of the aluminium particles may be less than about 20, 19, 18, 17, 16, 15, 14, 13, 12, 11, 10, 9, 8, 7, 6, 5, 4, 3, 2 or 1. Combinations of any two or more of these upper and/or lower particle sizes are also possible. The particle size is taken to be the longest cross-sectional diameter across an aluminium particle. For non-spherical aluminium particles, the particle size is taken to be the distance corresponding to the longest cross-section dimension across the particle.

The particle size can be measured by any standard method, for example laser diffraction, electron microscopy (e.g. TEM or SEM), X-ray diffraction (e.g. Scherrer equation), or dynamic light scattering. In one embodiment, the particle size can be measured using laser diffraction according to industry standard ISO 13320:2020.

In some embodiments, the aluminium component comprises an Al—Si alloy, an Al—Si eutectic alloy, an Al—B alloy, or combinations thereof. For example, as a p+ contact, the metal contains Al or Al—Si or Al—B alloys, or combinations thereof.

In some embodiments, the amount of the aluminium component dispersed in the patterning vehicle may be in an amount of between about 40 wt % to about 85 wt % based on the total weight of the paste composition. In some embodiments, the aluminium component dispersed in the patterning vehicle may be in an amount (in wt. %) of at least about 40, 45, 50, 55, 60, 65, 70, 75, 80, or 85 based on the total weight of the paste composition. In some embodiments, the aluminium component dispersed in the patterning vehicle may be in an amount (in wt. %) of less than about 85, 80, 75, 70, 65, 60, 55, 50, 45 or 40 based on the total weight of the paste composition. Combinations of any two or more of these upper and/or lower amounts are also possible.

In some embodiments, the amount of the glass component dispersed in the patterning vehicle may be in an amount of between about 0.1 wt. % to about 20 wt. % based on the total weight of the paste composition. In some embodiments, the glass component dispersed in the patterning vehicle may be in an amount (in wt. %) of at least about 0.1, 0.5, 1, 2, 3, 4, 5, 6, 7, 8, 9, 10, 11, 12, 13, 14, 15, 16, 17, 18, 19 or 20 based on the total weight of the paste composition. In some embodiments, the glass component dispersed in the patterning vehicle may be in an amount (in wt. %) of less than about 20, 19, 18, 17, 16, 15, 14, 13, 12, 11, 10, 9, 8, 7, 6, 5, 4, 3, 2, 1, 0.5 or 0.1 based on the total weight of the paste composition. Combinations of any two or more of these upper and/or lower amounts are also possible.

In some embodiments, the amount of silver particles dispersed in the patterning vehicle may be in an amount of less than about 0.5 wt. % when the aluminium content is provided in an amount of less than about 80 wt. % based on the total weight of the paste composition.

In some embodiments, the amount of the patterning vehicle may be provided in an amount of between about 5 wt. % to about 50 wt. % based on the total weight of the paste composition. In some embodiments, the patterning vehicle may be in an amount (in wt. %) of at least about 5, 10, 15, 20, 25, 30, 35, 40, 45 or 50 based on the total weight of the paste composition. In some embodiments, the patterning vehicle may be in an amount (in wt. %) of less than about 50, 45, 40, 35, 30, 25, 20, 15, 10 or 5 based on the total weight of the paste composition. Combinations of any two or more of these upper and/or lower amounts are also possible.

The glass component comprising glass frit (A) and glass frit (B) may be formed in-situ by the use of optional organometallic compounds that on pyrolysis, produce the chemically active element(s). The organometallic compounds can be deployed as an optional insoluble or soluble component in the patterning vehicle.

The glass component may be incorporated and mixed with the aluminium component as a preparation including patterning vehicle with a rheology adapted for patterning using techniques known in the art such as screen printing, pen writing, ink jet printing, extrusion processes and the like. The patterning vehicle is designed to be compatible for processing by drying and firing. The patterning vehicle is designed to sustain the dispersed nature of the suspended solids.

In some embodiment, the viscosity of the paste composition may be in the range of between about 5 to about 200 Pa·s. In some embodiments, the viscosity (in Pa·s) of the paste composition may be at least about 5, 10, 15, 20, 25, 30, 35, 40, 45, 50, 55, 60, 65, 70, 75, 80, 85, 90, 95, 100, 110, 120, 130, 140, 150, 160, 170, 180, 190, or 200. In some embodiments, the viscosity (in Pa·s) of the paste composition may be less than about 200, 190, 180, 170, 160, 150, 140, 130, 120, 110, 100, 95, 90, 85, 80, 70, 60, 50, 40, 30, 20, 10 or 5. Combinations of any two or more of these upper and/or lower viscosity values are also possible. All viscosity values recited herein may be at a given shear rate. In embodiments the shear rate may be that as used in any accepted standard testing approach in the art.

In some embodiments, the shear rate of the paste composition set to monitor design target viscosity is typically about 4 sec⁻¹.

### Bifacial PERC Solar Cell

The present disclosure also relates to a bifacial PERC solar cell comprising a silicon substrate and a rear contact thereon. In some embodiments, the silicon substrate may be crystalline silicon with morphology that is either mono crystalline or multi-crystalline. In some embodiments, the rear contact may comprise a passivation layer at least partially coated with a fired back contact paste at the rear side of the silicon substrate. The back contact paste is a fire-through aluminium paste composition, as described herein, to selectively fire through the passivation layer, wherein, prior to firing, the fire-through aluminium paste composition, comprises, an aluminium component, a glass component, and a patterning vehicle. The paste composition may further comprise silver particles or other silver source and/or optional additives. In some embodiments, the paste composition may comprise or consist of an aluminium content, glass component, patterning vehicle, optional silver particles or other silver source, and optional additives. The aluminium component, glass component, patterning vehicle, optional silver particles or other silver source, and optional additives may be selected from any one or more of the embodiments or examples as described herein.

In some embodiments, the solar cell may be p-type or n-type. Preferably, the solar cell may be p-type. In some embodiments, the passivation layer may comprise SiNₓ, SiNₓH_{y}, AlOx/SiNₓ, AlOx/SiNₓH_{y}, SiO₂/AlOx/SiNₓ or SiO₂/AlOx/SiNₓH_{y} deposited on the silicon substrate.

In some embodiments, the thickness of the silicon substrate may be less than about 150 μm. For example, the thickness of the silicon substrate may be less than about 125 μm. In one example, the thickness of the silicon substrate may be about 90 μm. It will be appreciated that the thickness of the silicon substrate and bowing is implicitly linked to the lateral dimension. As mentioned above, excessive bowing means that solar cells need to be formed from silicon substrates above a certain threshold thickness (e.g. 160 μm) related to the lateral dimension to reduce differential thermal expansion bowing effects and retain flatness and thus prevent breakage during cell handling, cell interconnection, placement and panel assembly in production. Metallization coverage and thickness is a prevailing factor in determining bowing.

In some embodiments, the thickness of the SiNₓ or SiNₓH_{y} coating may be in a range of between about 30 nm and about 200 nm. In some embodiments, the thickness of the SiNₓ or SiNₓH_{y} coating (in nm) may be at least 30, 35, 40, 45, 50, 55, 60, 65, 70, 75, 80, 85, 90, 95, 100, 110, 120, 130, 140, 150, 160, 170, 180, 190, or 200. In some embodiments, the thickness of the SiNₓ or SiNₓH_{y} coating (in nm) may be less than about 200, 190, 180, 170, 160, 150, 140, 130, 120, 110, 100, 95, 90, 85, 80, 75, 70, 65, 60, 55, 50, 45, 40, 35, or 30. Combinations of any two or more of these upper and/or lower thickness values are also possible. For example, the thickness of the SiNₓ or SiNₓH_{y} coating may be in a range of between about 50 nm and about 100 nm.

In some embodiments, the thickness of the AlOx may be in a range of between about 2 nm and about 20 nm. In some embodiments, the thickness of the AlOx (in nm) may be at least 2, 5, 7, 10, 12, 15, 18 or 20. In some embodiments, the thickness of the AlOx (in nm) may be less than about 20, 18, 15, 12, 10, 7, 5, or 2. Combinations of any two or more of these upper and/or lower thickness values are also possible. For example, the thickness of the AlOx may be in a range of between 7 nm and about 12 nm.

It will be appreciated that laser ablation or chemical etching may be used, but is preferably not applied at the cell back side to form a local opening.

The preparation and patterning process may be designed to provide or access to a resistive network after processing. In some embodiments, the paste composition may be patterned to form dots or lines on the passivation layer. For example, the patterns can be lines, lines that show meandering, dots, donuts and others that maximize the edge length (fractal length).

The pattern mask (e.g. screen) that may be used to pattern the contacting paste composition can be designed to be compatible with the objectives of the electronic device. For example, for a bifacial PERC solar cell, the formation of a p+ ohmic contact to be interconnected with the solar cell array using either lines, dots or other pattern to extract current from the cell. The patterning process is designed to control the cross sectional thickness of the print (i.e., paste composition) after printing and firing. As referred to above the thickness of the fired print will affect the partial pressure of oxygen and so the reaction path and whether the SiNx layer is fired through to contact the silicon to enable access of Al to Si thereby driving Al—Si alloy formation, the precursor to an Al doped Si lattice.

The conductor pattern can be designed to gain from the benefits of the present disclosure where Al—Si contact formation may be preferred to be localised at the edge of the print while underneath the pattern, the passivation stack function is maintained and thereby maximising the open circuit voltage. The localisation area can be controlled by the thickness of the printed layer, the porosity of the layer and/or the volume of liquid containing the oxidizing species (cation) below a limit determined by the composition of the firing paste composition. As discussed, the porosity, where it is interconnected, may be important as a conduit for oxygen. Conversely, passivation underneath the metallization (i.e., Al—Si alloy formation) can be retained by increasing the thickness, decreasing the free bulk porosity and/or increasing the liquid volume fraction in the system such as to change the reaction between the silicon nitride so that nitrogen is no longer evolved in the chemical reaction, viz, a reduction reaction. In some embodiments, the paste composition, post firing, facilitates aluminium metallisation on the back surface of the silicon substrate to form an Al—Si alloy at the edge of the fired back contact paste, wherein the edge of the fired back contact paste has a fired thickness of less than about 10 μm to form a localised back surface field.

In some embodiments, at least a portion of the paste composition may be patterned on the passivation layer to a fired thickness of less than about 10 μm. In some embodiments, at least a portion of the paste composition may be patterned on the passivation layer to a fired thickness greater than about 10 μm.

To maximize the open circuit voltage, the metallization design may be designed to maximise the fractal length of the edges and minimizing the area where the print thickness is above the SiNx threshold thickness that prevents fire through in an anaerobic reaction pathway (eq. 2 above).

The patterned article may be fired in a furnace that has a flow of air. The furnace may have the capability to manage the oxygen content by blending the air flow with nitrogen or other inert gas, such as argon.

In some embodiments, the surface area density of the fired back contact paste layer may be 0.8 mg/cm² to 5.5 mg/cm² where the area density at the edge being an important determining factor in functionality that is driven by the partial pressure of oxygen threshold for the reaction mechanism.

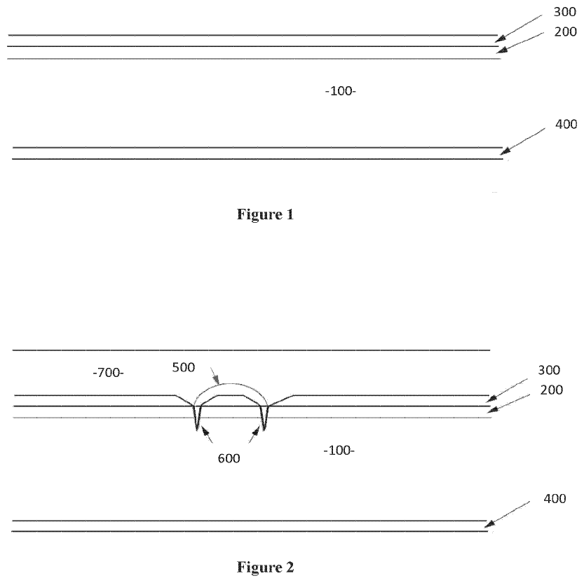

FIG. 1 illustrates a cross sectional view of a bifacial PERC solar cell with a silicon wafer substrate 100, a p-side aluminium oxide passivation layer 200, a p-side silicon nitride capping layer 300, and a n-side silicon nitride passivation layer 400 used to create a p-n junction. The thickness of the silicon wafer substrate 100 may be less than about 150 nm, preferably less than about 90 nm. The thickness of the aluminium oxide passivation layer 200 may be between about 2 nm to about 20 nm, preferably, between about 7 nm to about 12 nm. The thickness of the silicon nitride capping layer 300 may be between about 30 nm to about 200 nm, preferably between about 50 nm to about 100 nm.

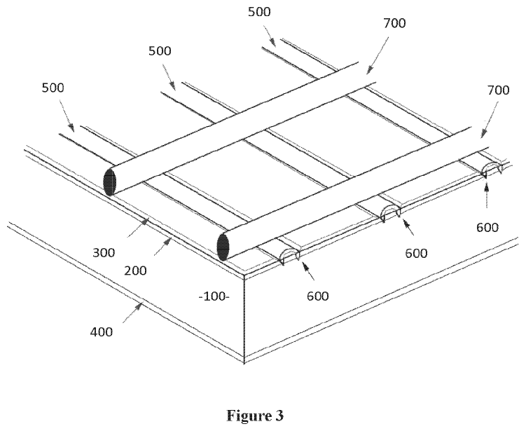

FIG. 2 illustrates a cross sectional view of a bifacial PERC solar cell with a silicon wafer substrate 100, a p-side aluminium oxide passivation layer 200, a p-side silicon nitride capping layer 300, and a n-side silicon nitride passivation layer 400. Printed p-side aluminium contact lines 500 may run above the p-side silicon nitride capping layer 300. Al/Si alloy contact points with silicon 600 penetrate through the p-side silicon nitride capping layer 300 and a p-side aluminium oxide passivation layer 200 to enable access of aluminium to silicon to facilitate contact metallisation and formation of a back surface field. Busbar or wire 700 sit above contacting the aluminium contact fingers 500.

FIG. 3 schematically illustrates an orthogonal view of a bifacial PERC solar cell with a silicon wafer substrate 100, a p-side aluminium oxide passivation layer 200, a p-side silicon nitride capping layer 300, and a n-side silicon nitride passivation layer 400. Printed p-side aluminium contact lines 500 run above the p-side silicon nitride capping layer 300. Al/Si alloy contact points with silicon 600 penetrate through the p-side silicon nitride capping layer 300 and a p-side aluminium oxide passivation layer 200 to enable access of aluminium to silicon to facilitate contact metallisation and formation of a back surface field. Busbar or wire 700 sit above contacting and run perpendicular to the aluminium contact fingers 500.

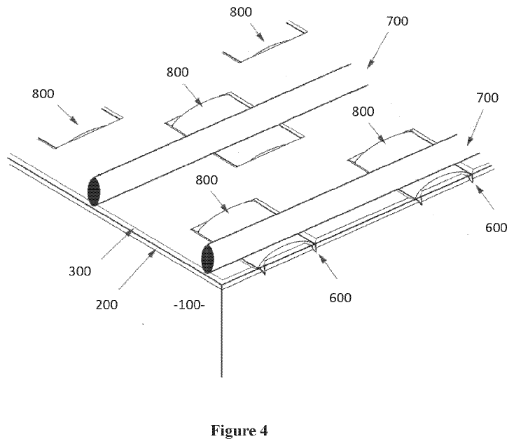

FIG. 4 schematically illustrates an orthogonal view of a bifacial PERC solar cell with a silicon wafer substrate 100, a p-side aluminium oxide passivation layer 200, and a p-Side silicon nitride capping layer 300. Printed p-side aluminium contact dots 800 sit above the p-side silicon nitride capping layer 300. Al/Si alloy contact points with silicon 600 penetrate through the p-side silicon nitride capping layer 300 and a p-side aluminium oxide passivation layer 200 to enable access of aluminium to silicon to facilitate contact metallisation and formation of a back surface field. Busbars or wires 700 sit above and contact the printed p-side aluminium contact pads 800.

### A Process for Preparing a Bifacial PERC Solar Cell

The present disclosure also relates to a process for preparing a bifacial PERC solar cell. The process comprising the steps of: providing a silicon substrate and a rear passivation layer thereon; applying a fire-through aluminium paste composition, as described herein, to at least partially coat the passivation layer to selectively fire through the passivation layer, the paste composition comprising an aluminium component, a glass component, and a patterning vehicle, wherein the glass component comprises at least a first glass frit (A) and a second glass frit (B), wherein the first glass frit (A) is an oxidizer of silicon nitride (SiNₓ) or hydrogenated silicon nitride (SiNₓ:H_{y}) and forms a low viscosity liquid at a predetermined temperature, and the second glass frit (B) does not comprise an oxidiser of silicon nitride (SiNₓ) or hydrogenated silicon nitride (SiNₓ:H_{y}) and controls the volume of the low viscosity liquid and the concentration of the first glass frit (A), heating the paste composition to a predetermined temperature to fire through at least a portion of the passivation layer to contact the silicon and enable access of aluminium to silicon to facilitate contact metallisation and formation of a back surface field. The paste composition may further comprise silver particles or other silver source and/or optional additives. In some embodiments, the paste composition may comprise or consist of an aluminium component, glass component, patterning vehicle, optional silver particles or other silver source, and optional additives. The aluminium component, glass component, patterning vehicle, optional silver particles or other silver source, and optional additives may be selected from any one or more of the embodiments or examples as described herein.

In some embodiments, the edge of the fired paste composition may have a fired thickness of less than about 10 μm to form the localised back surface field. The paste composition may be applied to the passivation layer using screen printing, pen writing, ink jet printing, or extrusion processes. In some embodiments, the paste composition may be applied to the passivation layer in the form dots or lines. The dot diameter or the line width may be in a range between about 20 μm to about 500 μm. In some embodiments, the dot diameter or the line width (in μm) may be at least 20, 30, 40, 50, 60, 70, 80, 90, 100, 120, 140, 160, 180, 200, 220, 240, 260, 280, 300, 320, 340, 360, 380, 400, 420, 440, 460, 480 or 500. In some embodiments, the dot diameter or the line width (in μm) may be less than about 500, 450, 400, 350, 300, 250, 200, 150, 100, 50 or 20. Combinations of any two or more of these upper and/or lower values are also possible.

In some embodiments, the passivation layer is not locally pre-opened using laser ablation or chemical etching.

In some embodiments, the heating step may be a two-step process of (i) drying the paste composition, and then (ii) firing the paste composition above the Al—Si eutectic or Al melting point temperature.

In some embodiments, the heating step may be a one-step process of (i) firing the wet paste composition above the Al—Si eutectic or Al melting point temperature.

In some embodiments, the predetermined temperature of heating step (i) may be in a range of between about 250° C. to about 350° C. In some embodiments, the predetermined temperature of heating step (ii) may be in a range of between about 500° C. to about 1000° C. For step (i), the temperature may be at least about 250, 260, 270, 280, 290, 300, 310, 320, 330, 340 or 350° C. The temperature for step (i) may be less than about 350, 340, 330, 320, 310, 300, 290, 280, 270, 260 or 250° C. Combinations of any two or more of these upper and/or lower temperatures are also possible. For step (ii), the temperature may be at least about 500, 550, 600, 650, 700, 750, 800, 850, 900, 950 or 1000° C. The temperature for step (ii) may be less than about 1000, 950, 900, 850, 800, 750, 700, 650, 600, 550 or 500° C. Combinations of any two or more of these upper and/or lower firing temperatures are also possible. It will be appreciated that the heating step is performed in an O₂ environment, or in other words in the presence of O₂.

In some embodiments, the passivation layer may comprise SiNₓ, SiNₓH_{y}, AlOx/SiNₓ, AlOx/SiNₓH_{y}, SiO₂/AlOx/SiNₓ or SiO₂/AlOx/SiNₓH_{y} deposited on the silicon substrate.

In some embodiments, the thickness of the silicon substrate may be less than about 150 μm. For example, the thickness of the silicon substrate may be less than about 125 μm. In one example, the thickness of the silicon substrate may be about 90 μm.

In some embodiments, the thickness of the SiNₓ or SiNₓH_{y} coating is in a range of between about 30 nm and about 200 nm. In some embodiments, the thickness of the SiNx or SiNxHy coating (in nm) may be at least 30, 35, 40, 45, 50, 55, 60, 65, 70, 75, 80, 85, 90, 95, 100, 110, 120, 130, 140, 150, 160, 170, 180, 190 or 200. In some embodiments, the thickness of the SiNx or SiNxHy coating (in nm) may be less than about 200, 190, 180, 170, 160, 150, 140, 130, 120, 110, 100, 95, 90, 85, 80, 75, 70, 65, 60, 55, 50, 45, 40, 35 or 30. Combinations of any two or more of these upper and/or lower values are also possible. For example, the thickness of the SiNₓ or SiNₓH_{y} coating may be in a range of between about 50 nm and about 100 nm.

In some embodiments, the thickness of the AlOx may be in a range of between about 2 nm and about 20 nm. In some embodiments, the thickness of the AlOx (in nm) may be at least 2, 5, 7, 10, 12, 15, 18 or 20. In some embodiments, the thickness of the AlOx (in nm) may be less than about 20, 18, 15, 12, 10, 7, 5 or 2. Combinations of any two or more of these upper and/or lower values are also possible. For example, the thickness of the AlOₓ may be in a range of between 7 nm and about 12 nm.

In some embodiments, the process may further comprise applying a multi-wire grid to the back side of the cell, and optionally applying the multi-wire grid to the front surface of the silicon substrate, to interconnect the cells. Interconnection can be done with a network that enables contact with the p+. For example, Smartwire technology may be used and provided by Meyer Burger AG. In some embodiments, the multi-wire grid may comprise between about 15 and about 50 wires. The wires may be Cu-based wires coated with a low melting-point alloy. The intent is to enable interconnection of the Al fire through contact areas on the backside with the front side metallisation contacts on the next cell as per a stringing operation.

In some embodiments, one or more cells may be arranged to be interconnected in a series or parallel. In some embodiments, the cells may be encased in a module with glass, wherein the glass thickness is between about 1 mm to about 4 mm.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

The present disclosure may be described by the following embodiments:

A fire-through aluminium paste composition to selectively fire through a passivation layer, the paste composition comprising: an aluminium component, a glass component, and a patterning vehicle; wherein the glass component comprises at least a first glass frit (A) and a second glass frit (B), wherein the first glass frit (A) is an oxidizer of silicon nitride (SiNₓ) or hydrogenated silicon nitride (SiNₓ:H_{y}) and forms a low viscosity liquid at a predetermined temperature, and the second glass frit (B) does not comprise an oxidiser of silicon nitride (SiNₓ) or hydrogenated silicon nitride (SiNₓ:H_{y}) and controls the volume of the low viscosity liquid and the concentration of the first glass frit (A).

The fire-through aluminium paste composition according to any one or more embodiments described herein, wherein the aluminium component comprises aluminium particles.

The fire-through aluminium paste composition according to any one or more embodiments described herein, wherein mean average aluminium particle size is between about 1 μm to about 20 μm.

The fire-through aluminium paste composition according to any one or more embodiments described herein, wherein the mean average aluminium particle size is between about 4 μm to about 8 μm.

The fire-through aluminium paste composition according to any one or more embodiments described herein, wherein the aluminium particles are spherical, nodular, flaked, colloidal, amorphous, or combinations thereof.

The fire-through aluminium paste composition according to any one or more embodiments described herein, wherein the aluminium component comprises an Al—Si alloy, an Al—Si eutectic alloy, an Al—B alloy, or combinations thereof.

The fire-through aluminium paste composition according to any one or more embodiments described herein, wherein the first glass frit (A) is selected from the group consisting of Pb based glass, Bi based glass, Bi—Zn based glass, Bi—Zn—B based glass, Te based glass, Bi—Te based glass, V based glass, or combinations thereof.

The fire-through aluminium paste composition according to any one or more embodiments described herein, wherein the D50 particle size of the glass component is about 0.1 microns to about 20 microns.

The fire-through aluminium paste composition according to any one or more embodiments described herein, wherein the paste composition further comprises silver particles or other silver source.

The fire-through aluminium paste composition according to any one or more embodiments described herein, mean average silver particle size is between about 0.03 μm to about 5 μm.

The fire-through aluminium paste composition according to any one or more embodiments described herein, wherein the silver particles are present in an amount of less than about 0.5 wt. % based on the total weight of the paste composition.

The fire-through aluminium paste composition according to any one or more embodiments described herein, wherein the silver particles are present in an amount of less than about 0.2 wt. % based on the total weight of the paste composition.

The fire-through aluminium paste composition according to any one or more embodiments described herein, wherein: the aluminium component is present in an amount of between about 40 wt. % to about 85 wt. % based on the total weight of the paste composition, the glass component is present in an amount of between about 0.05 wt. % to about 20 wt. % based on the total weight of the paste composition, and the patterning vehicle is present in an amount of between about 5 wt. % to about 50 wt. % based on the total weight of the paste composition.

The fire-through aluminium paste composition according to any one or more embodiments described herein, wherein the paste further comprises silver particles, wherein the silver particles are present in an amount of less than about 0.5 wt. % when the aluminium content is present in an amount of less than about 80 wt. % based on the total weight of the paste composition.

The fire-through aluminium paste composition according to any one or more embodiments described herein, wherein the viscosity of the paste composition is in the range of between about 5 Pa·s to about 200 Pa·s appropriate for the patterning process being used.

The fire-through aluminium paste composition according to any one or more embodiments described herein, wherein the shear rate of the paste composition set to monitor design target viscosity is typically about 4 sec⁻¹.

The fire-through aluminium paste composition according to any one or more embodiments described herein, further comprising one or more organic or inorganic additives.

A process for preparing a fire-through aluminium paste composition to selectively fire through a passivation layer, comprising: providing an aluminium component and a glass component, and dispersing the aluminium component and the glass component in a patterning vehicle to form the fire-through aluminium paste composition, wherein the glass component comprises at least a first glass frit (A) and a second glass frit (B), wherein the first glass frit (A) is an oxidizer of silicon nitride (SiNx) or hydrogenated silicon nitride (SiNx:Hy) and forms a low viscosity liquid at a predetermined temperature, and the second glass frit (B) does not comprise an oxidiser of silicon nitride (SiNx) or hydrogenated silicon nitride (SiNx:Hy) and controls the volume of the low viscosity liquid and the concentration of the first glass frit (A).

The process for preparing a fire-through aluminium paste composition to selectively fire through a passivation layer according to any one or more embodiments described herein, further comprising dispersing silver particles in the patterning vehicle.

The process for preparing a fire-through aluminium paste composition to selectively fire through a passivation layer according to any one or more embodiments described herein, wherein the aluminium component comprises aluminium particles and has a mean average aluminium particle size of between about 1 μm to about 20 μm.

The process for preparing a fire-through aluminium paste composition to selectively fire through a passivation layer according to any one or more embodiments described herein, wherein the mean average aluminium particle size is between about 4 μm to about 8 μm.

The process for preparing a fire-through aluminium paste composition to selectively fire through a passivation layer according to any one or more embodiments described herein, wherein the aluminium component comprise an Al—Si alloy, an Al—Si eutectic alloy, an Al—B alloy, or combinations thereof.

The process for preparing a fire-through aluminium paste composition to selectively fire through a passivation layer according to any one or more embodiments described herein, wherein the amount of the aluminium component dispersed in the patterning vehicles is in an amount of between about 40 wt. % to about 85 wt. % based on the total weight of the paste composition.

The process for preparing a fire-through aluminium paste composition to selectively fire through a passivation layer according to any one or more embodiments described herein, wherein the amount of the patterning vehicle is provided in an amount of between about 5 wt. % to about 50 wt. % based on the total weight of the paste composition.

The process for preparing a fire-through aluminium paste composition to selectively fire through a passivation layer according to any one or more embodiments described herein, wherein the amount of the glass component dispersed in the patterning vehicles is in an amount of between about 0.05 wt. % to about 20 wt. % based on the total weight of the paste composition.

The process for preparing a fire-through aluminium paste composition to selectively fire through a passivation layer according to any one or more embodiments described herein, wherein the amount of silver particles dispersed in the patterning vehicle is in an amount of less than about 0.5 wt. % when the aluminium content is provided in an amount of less than about 80 wt. % based on the total weight of the paste composition.

The process for preparing a fire-through aluminium paste composition to selectively fire through a passivation layer according to any one or more embodiments described herein, wherein the viscosity of the paste composition is in a range of between about 5 to about 200 Pa·s.

The process for preparing a fire-through aluminium paste composition to selectively fire through a passivation layer according to any one or more embodiments described herein, wherein the shear rate of the paste composition set to monitor design target viscosity is typically about 4 sec⁻¹.

The process for preparing a fire-through aluminium paste composition to selectively fire through a passivation layer according to any one or more embodiments described herein, further comprising one or more additives dispersed in the printing vehicle.

A fire-through aluminium paste composition to selectively fire through a passivation layer prepared according to any one or more embodiments described herein of the process for preparing a fire-through aluminium paste composition to selectively fire through a passivation layer.

A fired back contact paste adhered to a passivation layer of a bifacial PERC solar cell comprising a silicon substrate, wherein the passivation layer is fired through to contact the silicon and enable access of aluminium to silicon for the formation of an Al—Si alloy, wherein the fired back contact paste, prior to firing, is a fire-through paste composition comprising: an aluminium component, a glass component, and a patterning vehicle; wherein the glass component comprises at least a first glass frit (A) and a second glass frit (B), wherein the first glass frit (A) is an oxidizer of silicon nitride (SiNx) or hydrogenated silicon nitride (SiNx:Hy) and forms a low viscosity liquid at a predetermined temperature, and the second glass frit (B) does not comprise an oxidiser of silicon nitride (SiNx) or hydrogenated silicon nitride (SiNx:Hy) and controls the volume of the low viscosity liquid and the concentration of the first glass frit (A).

The fired back contact paste according to any one or more embodiments described herein, wherein the Al—Si alloy formation is localised at the edge of the print while underneath the pattern, the passivation layer function is maintained maximising the open circuit voltage.

The fired back contact paste according to any one or more embodiments described herein, wherein the localised area is controlled by the thickness and/or porosity of the fired back contact paste layer.

The fired back contact paste according to any one or more embodiments described herein, wherein at least a portion of the thickness of the fired back contact paste layer is less than 10 μm to form a localised back surface field.

The fired back contact paste according to any one or more embodiments described herein, wherein at least a portion of the thickness of the fired back contact paste layer is greater than 10 μm to provide areas that do not penetrate the passivation layer through to the silicon substrate.

The fired back contact paste according to any one or more embodiments described herein, wherein the surface area density of the fired back contact paste layer may be 0.8 mg/cm² to 5.5 mg/cm² where the area density at the edge being an important determining factor in functionality that is driven by the partial pressure of oxygen threshold for the reaction mechanism.

A bifacial PERC solar cell comprising a silicon substrate and a rear contact thereon, the rear contact comprising a passivation layer at least partially coated with a fired back contact paste at the rear side of the silicon substrate, wherein the back contact paste is a fire-through aluminium paste composition to selectively fire through the passivation layer, wherein, prior to firing, the fire-through aluminium paste composition, comprises, an aluminium component, a glass component, and a patterning vehicle; wherein the glass component comprises at least a first glass frit (A) and a second glass frit (B), wherein the first glass frit (A) is an oxidizer of silicon nitride (SiNx) or hydrogenated silicon nitride (SiNx:Hy) and forms a low viscosity liquid at a predetermined temperature, and the second glass frit (B) does not comprise an oxidiser of silicon nitride (SiNx) or hydrogenated silicon nitride (SiNx:Hy) and controls the volume of the low viscosity liquid and the concentration of the first glass frit (A).

The bifacial PERC solar cell according to any one or more embodiments described herein, wherein the solar cell is p-type.

The bifacial PERC solar cell according to any one or more embodiments described herein, wherein the paste composition further comprises silver particles or other silver source.

The bifacial PERC solar cell according to any one or more embodiments described herein, wherein the passivation layer comprises SiNx, SiNxHy, AlOx/SiNx, AlOx/SiNxHy, SiO₂/AlOx/SiNx or SiO₂/AlOx/SiNxHy deposited on the silicon substrate.

The bifacial PERC solar cell according to any one or more embodiments described herein, wherein the thickness of the silicon substrate is less than about 150 μm.

The bifacial PERC solar cell according to any one or more embodiments described herein, wherein the thickness of the silicon substrate is less than about 125 μm.

The bifacial PERC solar cell according to any one or more embodiments described herein, wherein the thickness of the silicon substrate is about 90 μm

The bifacial PERC solar cell according to any one or more embodiments described herein, wherein the thickness of the SiNx or SiNxHy coating is in a range of between about 30 nm and about 200 nm.

The bifacial PERC solar cell according to any one or more embodiments described herein, wherein the thickness of the AlOx is in a range of between about 2 nm and about 20 nm.

The bifacial PERC solar cell according to some embodiments described herein, wherein laser ablation or chemical etching may not applied at the cell back side to form a local opening.

The bifacial PERC solar cell according to any one or more embodiments described herein, wherein the silicon substrate is crystalline silicon.

The bifacial PERC solar cell according to any one or more embodiments described herein, wherein the paste composition is patterned to form dots or lines on the passivation layer.

The bifacial PERC solar cell according to any one or more embodiments described herein, wherein at least a portion of the paste composition is patterned on the passivation layer to a fired thickness of less than about 10 μm.

The bifacial PERC solar cell according to any one or more embodiments described herein, wherein at least a portion of the paste composition is patterned on the passivation layer to a fired thickness greater than about 10 μm.

The bifacial PERC solar cell according to any one or more embodiments described herein, wherein, post firing, the paste composition facilitates aluminium metallisation on the back surface of the silicon substrate to form an Al—Si alloy at the edge of the fired back contact paste, wherein the edge of the fired back contact paste has a fired thickness of less than about 10 μm to form a localised back surface field.

The bifacial PERC solar cell according to any one or more embodiments described herein, wherein the surface area density of the fired back contact paste layer may be 0.8 mg/cm² to 5.5 mg/cm² where the area density at the edge being an important determining factor in functionality that is driven by the partial pressure of oxygen threshold for the reaction mechanism.

A process for preparing a bifacial PERC solar cell, comprising: providing a silicon substrate and a rear passivation layer thereon; applying a fire-through aluminium paste composition to at least partially coat the passivation layer to selectively fire through the passivation layer, the paste composition comprising an aluminium component, a glass component, and a patterning vehicle, wherein the glass component comprises at least a first glass frit (A) and a second glass frit (B), wherein the first glass frit (A) is an oxidizer of silicon nitride (SiNx) or hydrogenated silicon nitride (SiNx:Hy) and forms a low viscosity liquid at a predetermined temperature, and the second glass frit (B) does not comprise an oxidiser of silicon nitride (SiNx) or hydrogenated silicon nitride (SiNx:Hy) and controls the volume of the low viscosity liquid and the concentration of the first glass frit (A), heating the paste composition to a predetermined temperature to fire through at least a portion of the passivation layer to contact the silicon and enable access of aluminium to silicon to facilitate contact metallisation and formation of a back surface field.

The process for preparing a bifacial PERC solar cell according to any one or more embodiments described herein, wherein the edge of the fired paste composition has a fired thickness of less than about 10 μm to form the localised back surface field.

The process for preparing a bifacial PERC solar cell according to any one or more embodiments described herein, wherein the paste composition is applied to the passivation layer using screen printing, pen writing, ink jet printing, or extrusion processes.

The process for preparing a bifacial PERC solar cell according to any one or more embodiments described herein, wherein the paste composition is applied to the passivation layer in the form dots or lines.

The process for preparing a bifacial PERC solar cell according to any one or more embodiments described herein, wherein the dot diameter or the line width is in a range between about 20 μm to about 500 μm.

The process for preparing a bifacial PERC solar cell according to any one or more embodiments described herein, wherein the passivation layer is not locally pre-opened using laser ablation or chemical etching.

The process for preparing a bifacial PERC solar cell according to any one or more embodiments described herein, wherein the aluminium component further comprises silver particles or other silver source.

The process for preparing a bifacial PERC solar cell according to any one or more embodiments described herein, wherein the heating step is a two-step process of (i) drying the paste composition, and then (ii) firing the paste composition.

The process for preparing a bifacial PERC solar cell according to any one or more embodiments described herein, wherein the predetermined temperature of heating step (i) is in a range of between about 250° C. to about 350° C.

The process for preparing a bifacial PERC solar cell according to any one or more embodiments described herein, wherein the predetermined temperature of heating step (ii) is in a range of between about 500° C. to about 1000° C.

The process for preparing a bifacial PERC solar cell according to any one or more embodiments described herein, wherein the passivation layer comprises SiNx, SiNxHy, AlOx/SiNx, AlOx/SiNxHy, SiO₂/AlOx/SiNx or SiO₂/AlOx/SiNxHy deposited on the silicon substrate.

The process for preparing a bifacial PERC solar cell according to any one or more embodiments described herein, wherein the thickness of the silicon substrate is less than about 150 μm.

The process for preparing a bifacial PERC solar cell according to any one or more embodiments described herein, wherein the thickness of the silicon substrate is less than about 125 μm.

The process for preparing a bifacial PERC solar cell according to any one or more embodiments described herein, wherein the thickness of the silicon substrate is about 90 μm.

The process for preparing a bifacial PERC solar cell according to any one or more embodiments described herein, wherein the thickness of the SiNx or SiNxHy coating is in a range of between about 30 nm and about 200 nm.

The process for preparing a bifacial PERC solar cell according to any one or more embodiments described herein, wherein the thickness of the AlOx is in a range of between about 2 nm and about 20 nm.

The process for preparing a bifacial PERC solar cell according to any one or more embodiments described herein, further comprising applying a multi-wire grid to the back side of the cell, and optionally applying the multi-wire grid to the front surface of the silicon substrate, to interconnect the cells.

The process for preparing a bifacial PERC solar cell according to any one or more embodiments described herein, wherein the multi-wire grid comprises between about 15 and about 50 wires.

The process for preparing a bifacial PERC solar cell according to any one or more embodiments described herein, wherein the wires are Cu-based wires coated with a low melting-point alloy.

The process for preparing a bifacial PERC solar cell according to any one or more embodiments described herein, wherein one or more cells are arranged to be interconnected in a series or parallel.

The process for preparing a bifacial PERC solar cell according to any one or more embodiments described herein, wherein the cells are encased in a module with glass, wherein the glass thickness is between about 1 to about 4 mm.

The process for preparing a bifacial PERC solar cell according to any one or more embodiments described herein, wherein the cells are encased in a module comprised of a transparent substance that provides hermetic protection of the cell, wherein the transparent substance thickness is between about 1 to about 4 mm.

### EXAMPLES

The present disclosure is further described by the following examples. It is to be understood that the following description is for the purpose of describing particular examples only and is not intended to be limiting with respect to the above description.

### Example 1: Wafer Preparation

Monocrystalline p-type silicon wafers that were 156 mm square with a thickness of 160 μm were prepared. The saw damage was removed using processes known in the art. Both sides were textured using an alkali bath to produce a typical etch monocrystalline surface with 7 μm pyramids. The wafers were cleaned using the conventional approach known in the art.

A n-type diffusion was produced on one side, in a back to back diffusion process using POCl₃ in the conventional way. The sheet resistance of the emitter was designed to be approximately 100 ohm·cm.

A conventional silicon nitride (SiNx:Hy) anti-reflection passivation layer was applied by PECVD to provide a 60 nm layer on the emitter. The rear surface was etched with HNA acid (of composition known in the art) for 2 minutes. Additionally, a layer of SiOx of 2 nm thick can be formed to increase the Voc. In these examples, such a SiOx layer was not deployed. A stack passivation was constructed as PECVD AlOx layer and a capping layer of 60 nm thick SiNx:Hy. The AlOx layer thickness was varied as 0 nm, 7 nm, 12 nm and 20 nm to determine the impact on electrical and chemical performance.

### Example 2 Paste Preparation

Pastes were prepared with different amounts of Aluminium powder and frit content by cross blending two proprietary pastes. The first paste, ToyoAl TB-08E3-FTNoGF (referred to herein as A-0), consisted of 80 weight % Al powder dispersed in an organic vehicle. The second paste, ToyoAl TB-08E3-FTGFup (referred to herein as A-20), consisted of a blend of 2 proprietary glass frits and Al powder. The first proprietary glass, glass frit (A), was based on bismuth borosilicate where bismuth is the silicon nitride oxidiser. The second proprietary glass, glass frit (B), is based on an alkali/alkaline earth borosilicate glass where none of the constituents are known to oxidize silicon nitride. The blend ratio of the two glass frits is proprietary to ToyoAl. The Al content in TB-08E3-FTGFup is 65 weight % Al powder and 20 weight % glass frit. The two compositions were designed to be cross blendable, screen printable using the same organic patterning vehicle to facilitate printing experiments without the need for extra additions.

Blended mixtures of A-0 and A-20 were made up according to Table 1 to provide compositions with a range of frit concentrations against the aluminium content.

TABLE 1
Paste Blend Table

| | | | | | | | | Paste solids | | | |
|---|---|---|---|---|---|---|---|---|---|---|---|
| | | | | | | | | Composition | | Relative frit | |
| | target | | Low | Wt | | | Target | Wt % | Wt % | content | |
| Sample | % frit | % Al | frit | (g) | High frit | Wt (g) | Wt (g) | frit | Al | % frit | % Al |
| B-008 | 0.8% | 79.4% | A-0 | 126.00 | B-050 | 24.00 | 150 | 0.8% | 79.4% | 1.0% | 99.0% |
| B-015 | 1.5% | 78.9% | A-0 | 138.75 | A-20 | 11.25 | 150 | 1.5% | 78.9% | 1.9% | 98.1% |
| B-030 | 3.0% | 77.8% | A-0 | 127.50 | A-20 | 22.50 | 150 | 3.0% | 77.8% | 3.7% | 96.3% |
| B-050 | 5.0% | 76.3% | A-0 | 112.50 | A-20 | 37.50 | 150 | 5.0% | 76.3% | 6.2% | 93.8% |
| B-070 | 7.0% | 74.8% | A-0 | 97.50 | A-20 | 52.50 | 150 | 7.0% | 74.8% | 8.6% | 91.4% |
| B-080 | 8.0% | 74.0% | A-0 | 90.00 | A-20 | 60.00 | 150 | 8.0% | 74.0% | 9.8% | 90.2% |
| B-090 | 9.0% | 73.3% | A-0 | 82.50 | A-20 | 67.50 | 150 | 9.0% | 73.3% | 10.9% | 89.1% |
| B-120 | 12.0% | 71.0% | A-0 | 60.00 | A-20 | 90.00 | 150 | 12.0% | 71.0% | 14.5% | 85.5% |
| B-200 | 20.0% | 65.0% | A-0 | 0.00 | A-20 | 150.00 | 150 | 20.0% | 65.0% | 23.5% | 76.5% |

The pastes were stored separately until required for printing.

### Example 3 Printing and Drying

Blank (non-metalized) processed cells made according to Example 1, were laser etched with numbers for identification prior to processing for traceability purposes.

A standard front side n-type pattern designed for contacting 100 Ohm·sq emitter resistance was used to print a commercial silver paste from Hereaus GmbH. A screen design print width of 35 μm was used and lines were spaced at 1000 μm. A Baccini screen printer was used with printing parameters selected which are known to be appropriate for the paste and screen by those skilled in the art. Busbars were not applied and instead the Smartwire approach was used. The average Ag consumption was 45 mg per cell. The silver prints were dried in a Baccini carousel drier at 200° C. for 20 minutes.

Each of the aluminium pastes described in Table 1 was printed on an Ag printed cell. Each composition printed on the cells with each one of the SiOx-AlOx-SiNx passivation stacks denoted by their different AlOx thicknesses (all other stack parameters being constant). The screen used for the printing of the aluminium paste had 100 μm width parallel lines (155 lines per cell). The Aluminium consumption for these cells was approximately 250 mg per cell.

### Example 4 Firing

The printed cells were fired in a furnace made by Centrotherm GmbH that is a standard design for firing solar cells. The furnace had six firing zones (see Table 2). For each cell, the furnace was set up with the same profile and belt speed used to produce conventional full BSF cells (full area Aluminium printed on one side, with a conventional design front side grid configured without busbars for the emitter contact print). To optimise the firing profile and belt speed, contact resistance was used as a probe, the zone 5 and zone 6 settings were changed as 820° C., 840° C. and 890° C. in conjunction with changing the belt speed (2500 mm/min, 5400 mm/min and 7000 mm/min). Textured cells using 60 nm SiNx layer was used for this experiment. From this, the belt speed was set at 5400 mm/min.

TABLE 2
Furnace Zone Settings

| Zone 1 | Zone 2 | Zone 3 | Zone 4 | Zone 5 | Zone 6 |
|---|---|---|---|---|---|
| 540° C. | 570° C. | 570° C. | 610° C. | 840° C. | 840° C. |

Cells were fired with the n-type emitter (Ag metallization) face down. Prior to addition of the wafers to the furnace, 10 dummy wafers were positioned in front and behind the example printed cells to ensure that the furnace was thermally equilibrated.

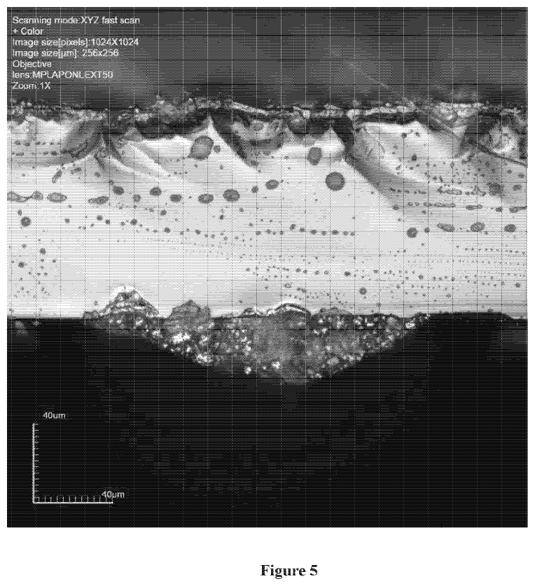

FIG. 5 is an optical image (Olympus OLS3000 laser microscope) of one example printed cell after firing showing Al—Si alloy formation being localised at the edge of the print while underneath the pattern, the passivation layer function is maintained maximising the open circuit voltage.

Measurement of the electrical properties of the cells were evaluated using a conventional solar measurement apparatus produced by Halm GmbH. The cells were held in a rig designed by Meyer-Burger S.A. to simulate measurements using an 12 wire Smartwire interconnect system. The wires were not soldered into place as this is a measurement test rig. The Meyer Burger system was used to simulate a multiwire interconnection configuration. The contact resistance was evaluated on a tool made by GP Solar GmbH.

### Example 5 Performance of the PERC Cells

The impact of the glass content on the electrical performance of a passivation stack was compared to having only SiNx as a capping layer.

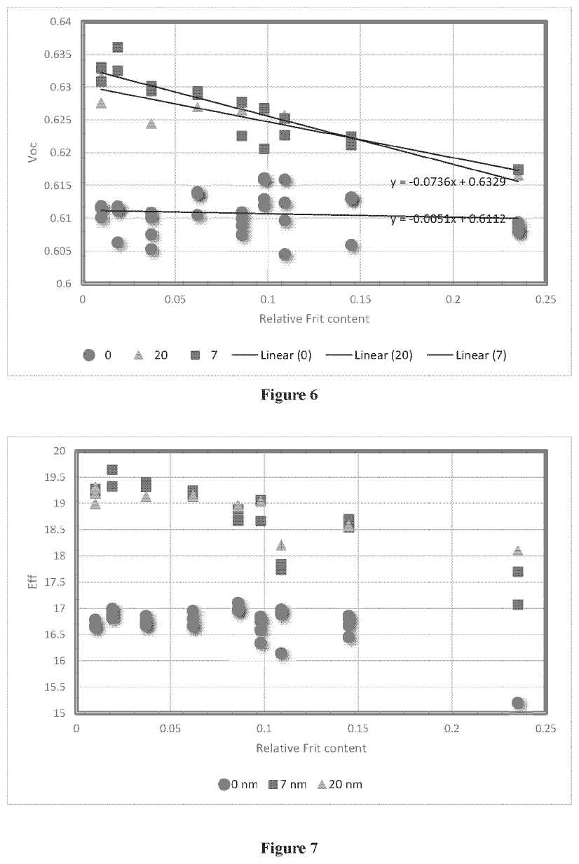

The results of the impact of frit content on the AlOx passivation thickness are shown in FIG. 6. There is no dependence of the Voc on the relative frit content in the fired film when there is no AlOx in the stack. When AlOx layer is present in the stack, there is degradation of the Voc and a passivation effect is observed with increasing glass frit. It appears that this effect may be due to the dissolution of the AlOx by the glass frit or more contact being made, and the passivation stack being removed underneath the metallisation.

It has been unexpectedly found that fire through is advantageously occurring at very low glass frit content in the fired glass-metal compact with a trend that indicates that the Voc could be even higher at lower frit content. Print thickness is also a determining variable.

The impact of AlOx thickness on cell efficiency is shown in FIG. 7. Increased relative frit content degraded the AlOx-SiNx passivation stack. Conversely, the SiNx layer did not demonstrate any impact of the glass concentration on the electrical performance. It has been unexpectedly found that low and very low frit content provides optimum benefit from the passivation stack.

Advantageously, no measurable bowing was detected in the cells prepared and described herein.

It has been found that the composition of the aluminium paste as described herein can be designed to enable further reduction of the thickness of the AlOx component of the passivation stack to advantageously maximise the electrical performance of the PERC solar cell, for example, by increasing the open circuit voltage.

1. A fire-through aluminium paste composition to selectively fire through a passivation layer, the paste composition comprising:
an aluminium component,
a glass component, and
a patterning vehicle;
wherein the glass component comprises at least a first glass frit (A) and a second glass frit (B), wherein the first glass frit (A) is an oxidizer of silicon nitride (SiNₓ) or hydrogenated silicon nitride (SiNₓ:H_{y}) and forms a low viscosity liquid at a predetermined temperature, and the second glass frit (B) does not comprise an oxidiser of silicon nitride (SiNₓ) or hydrogenated silicon nitride (SiNₓ:H_{y}) and controls the volume of the low viscosity liquid and the concentration of the first glass frit (A).

2. The paste composition of claim 1, wherein the aluminium component comprises aluminium particles.

3. The paste composition of claim 2, wherein mean average aluminium particle size is between about 1 μm to about 20 μm.

4. The paste composition of claim 2 or claim 3, wherein the mean average aluminium particle size is between about 4 μm to about 8 μm.

5. The composition of any one of claims 2 to 4, wherein the aluminium particles are spherical, nodular, flaked, colloidal, amorphous, or combinations thereof.

6. The paste composition of any one of the preceding claims, wherein the aluminium component comprises an Al—Si alloy, an Al—Si eutectic alloy, an Al—B alloy, or combinations thereof.

7. The paste composition of any one of the preceding claims, wherein the first glass frit (A) is selected from the group consisting of Pb based glass, Bi based glass, Bi—Zn based glass, Bi—Zn—B based glass, Te based glass, Bi—Te based glass, V based glass, or combinations thereof.

8. The paste composition of any one of the preceding claims, wherein the D₅₀ particle size of the glass component is about 0.1 microns to about 20 microns.

9. The paste composition of any one of the preceding claims, wherein the paste composition further comprises silver particles or other silver source.

10. The paste composition of claim 10, mean average silver particle size is between about 0.03 μm to about 5 μm.

11. The paste composition of claim 9 or claim 10, wherein the silver particles are present in an amount of less than about 0.5 wt. % based on the total weight of the paste composition.

12. The paste composition of any one of claims 9 to 11, wherein the silver particles are present in an amount of less than about 0.2 wt. % based on the total weight of the paste composition.

13. The paste composition of any one of the preceding claims, wherein:
the aluminium component is present in an amount of between about 40 wt. % to about 95 wt. % based on the total weight of the paste composition,
the glass component is present in an amount of between about 0.1 wt. % to about 20 wt. % based on the total weight of the paste composition, and
the patterning vehicle is present in an amount of between about 5 wt. % to about 50 wt. % based on the total weight of the paste composition.

14. The paste composition of claim 13 further comprises silver particles or other silver source, wherein the silver particles or other silver source are present in an amount of less than about 0.5 wt. % when the aluminium content is present in an amount of less than about 80 wt. % based on the total weight of the paste composition.

15. The paste composition of any one of the preceding claims, wherein the viscosity of the paste composition is in the range of between about 5 to about 200 Pa·s.

16. The paste composition of any one of the preceding claims, wherein the shear rate of the paste composition set to monitor design target viscosity is typically about 4 sec⁻¹.

17. The paste composition of any one of the preceding claims further comprising one or more organic or inorganic additives.

18. A process for preparing a fire-through aluminium paste composition to selectively fire through a passivation layer, comprising:
(i) providing an aluminium component and a glass component, and
(ii) dispersing the aluminium component and the glass component in a patterning vehicle to form the fire-through aluminium paste composition,
wherein the glass component comprises at least a first glass frit (A) and a second glass frit (B), wherein the first glass frit (A) is an oxidizer of silicon nitride (SiNₓ) or hydrogenated silicon nitride (SiNₓ:H_{y}) and forms a low viscosity liquid at a predetermined temperature, and the second glass frit (B) does not comprise an oxidiser of silicon nitride (SiNₓ) or hydrogenated silicon nitride (SiNₓ:H_{y}) and controls the volume of the low viscosity liquid and the concentration of the first glass frit (A).

19. The process of claim 18, further comprising dispersing silver particles in the patterning vehicle.

20. The process of claim 18 or claim 19, wherein the aluminium component comprises aluminium particles and has a mean average aluminium particle size of between about 1 μm to about 20 μm.

21. The process of claim 20, wherein the mean average aluminium particle size is between about 4 μm to about 8 μm.

22. The process of any one of claims 18 to 21, wherein the aluminium component comprise an Al—Si alloy, an Al—Si eutectic alloy, an Al—B alloy, or combinations thereof.

23. The process of any one of claims 18 to 22, wherein the amount of the aluminium component dispersed in the patterning vehicles is in an amount of between about 40 wt. % to about 85 wt. % based on the total weight of the paste composition.

24. The process of any one of claims 18 to 23, wherein the amount of the patterning vehicle is provided in an amount of between about 5 wt. % to about 50 wt. % based on the total weight of the paste composition.

25. The process of any one of claims 18 to 24, wherein the amount of the glass component dispersed in the patterning vehicles is in an amount of between about 0.05 wt. % to about 20 wt. % based on the total weight of the paste composition.

26. The process of any one of claims 19 to 25, wherein the amount of silver particles dispersed in the patterning vehicle is in an amount of less than about 0.5 wt. % when the aluminium content is provided in an amount of less than about 80 wt. % based on the total weight of the paste composition.

27. The process of any one of claims 18 to 26, wherein the viscosity of the paste composition is in a range of between about 5 to about 200 Pa·s.

28. The process of any one of claims 18 to 22, wherein the shear rate of the paste composition set to monitor design target viscosity is typically about 4 sec⁻¹.

29. The process of any one of claims 18 to 28, further comprising one or more additives dispersed in the printing vehicle.

30. A fire-through aluminium paste composition to selectively fire through a passivation layer prepared by the process according to any of claims 18 to 29.

31. A fired back contact paste adhered to a passivation layer of a bifacial PERC solar cell comprising a silicon substrate, wherein the passivation layer is fired through to contact the silicon and enable access of aluminium to silicon for the formation of an Al—Si alloy, wherein the fired back contact paste, prior to firing, is a fire-through paste composition comprising:
an aluminium component,
a glass component, and
a patterning vehicle;
wherein the glass component comprises at least a first glass frit (A) and a second glass frit (B), wherein the first glass frit (A) is an oxidizer of silicon nitride (SiNₓ) or hydrogenated silicon nitride (SiNₓ:H_{y}) and forms a low viscosity liquid at a predetermined temperature, and the second glass frit (B) does not comprise an oxidiser of silicon nitride (SiNₓ) or hydrogenated silicon nitride (SiNₓ:H_{y}) and controls the volume of the low viscosity liquid and the concentration of the first glass frit (A).

32. The fired back contact paste of claim 31, wherein the Al—Si alloy formation is localised at the edge of the print while underneath the pattern, the passivation layer function is maintained maximising the open circuit voltage.

33. The fired back contact paste of claim 32, wherein the localised area is controlled by the thickness and/or porosity of the fired back contact paste layer.

34. The fired back contact paste of claim 33, wherein at least a portion of the thickness of the fired back contact paste layer is less than 10 μm to form a localised back surface field.

35. The fired back contact paste of claim 33, wherein at least a portion of the thickness of the fired back contact paste layer is greater than 10 μm to provide areas that do not penetrate the passivation layer through to the silicon substrate.

36. The fired back contact paste of any one of claims 31 to 35, wherein the surface area density of the fired back contact paste layer is about 0.8 mg/cm² to about 5.5 mg/cm².

37. A bifacial PERC solar cell comprising a silicon substrate and a rear contact thereon, the rear contact comprising a passivation layer at least partially coated with a fired back contact paste at the rear side of the silicon substrate, wherein the back contact paste is a fire-through aluminium paste composition to selectively fire through the passivation layer, wherein, prior to firing, the fire-through aluminium paste composition, comprises,
an aluminium component,
a glass component, and
a patterning vehicle;
wherein the glass component comprises at least a first glass frit (A) and a second glass frit (B), wherein the first glass frit (A) is an oxidizer of silicon nitride (SiNₓ) or hydrogenated silicon nitride (SiNₓ:H_{y}) and forms a low viscosity liquid at a predetermined temperature, and the second glass frit (B) does not comprise an oxidiser of silicon nitride (SiNₓ) or hydrogenated silicon nitride (SiNₓ:H_{y}) and controls the volume of the low viscosity liquid and the concentration of the first glass frit (A).

38. The solar cell of claim 37, wherein the solar cell is p-type.

39. The solar cell of claim 37 or claim 38, wherein the paste composition further comprises silver particles or other silver source.

40. The solar cell of any one of claims 37 to 39, wherein the passivation layer comprises SiNₓ, SiNₓH_{y}, AlOx/SiNₓ, AlOx/SiNₓH_{y}, SiO₂/AlOx/SiNₓ or SiO₂/AlOx/SiNₓH_{y} deposited on the silicon substrate.

41. The solar cell of any one of claims 37 to 40, wherein the thickness of the silicon substrate is less than about 150 μm.

42. The solar cell of any one of claims 37 to 41, wherein the thickness of the silicon substrate is less than about 125 μm.

43. The solar cell of any one of claims 37 to 42, wherein the thickness of the silicon substrate is about 90 μm

44. The solar cell of any one of claims 37 to 43, wherein the thickness of the SiNₓ or SiNₓH_{y} coating is in a range of between about 30 nm and about 200 nm.

45. The solar cell of any one of claims 37 to 44, wherein the thickness of the AlOx is in a range of between about 2 nm and about 20 nm.

46. The solar cell of any one of claims 37 to 45, wherein laser ablation or chemical etching is not applied at the cell back side to form a local opening.

47. The solar cell of any one of claims 37 to 46, wherein the silicon substrate is crystalline silicon.

48. The solar cell of any one of claims 33 to 46, wherein the paste composition is patterned to form dots or lines on the passivation layer.

49. The solar cell of any one of claims 37 to 48, wherein at least a portion of the paste composition is patterned on the passivation layer to a fired thickness of less than about 10 μm.

50. The solar cell of any one of claims 37 to 48, wherein at least a portion of the paste composition is patterned on the passivation layer to a fired thickness greater than about 10 μm.

51. The solar cell of any one of claims 37 to 49, wherein, post firing, the paste composition facilitates aluminium metallisation on the back surface of the silicon substrate to form an Al—Si alloy at the edge of the fired back contact paste, wherein the edge of the fired back contact paste has a fired thickness of less than about 10 μm to form a localised back surface field.

52. The solar cell of claim 48, wherein the surface area density of the fired back contact paste layer is about 0.8 mg/cm² to about 5.5 mg/cm².

53. A process for preparing a bifacial PERC solar cell, comprising:
providing a silicon substrate and a rear passivation layer thereon;
applying a fire-through aluminium paste composition to at least partially coat the passivation layer to selectively fire through the passivation layer, the paste composition comprising an aluminium component, a glass component, and a patterning vehicle, wherein the glass component comprises at least a first glass frit (A) and a second glass frit (B), wherein the first glass frit (A) is an oxidizer of silicon nitride (SiNₓ) or hydrogenated silicon nitride (SiNₓ:H_{y}) and forms a low viscosity liquid at a predetermined temperature, and the second glass frit (B) does not comprise an oxidiser of silicon nitride (SiNₓ) or hydrogenated silicon nitride (SiNₓ:H_{y}) and controls the volume of the low viscosity liquid and the concentration of the first glass frit (A),
heating the paste composition to a predetermined temperature to fire through at least a portion of the passivation layer to contact the silicon and enable access of aluminium to silicon to facilitate contact metallisation and formation of a back surface field.

54. The process of claim 53, wherein the edge of the fired paste composition has a fired thickness of less than about 10 μm to form the localised back surface field.

55. The process of claim 53 of claim 54, wherein the paste composition is applied to the passivation layer using screen printing, pen writing, ink jet printing, or extrusion processes.

56. The process of any one of claims 53 to 55, wherein the paste composition is applied to the passivation layer in the form dots or lines.

57. The process of claim 54, wherein the dot diameter or the line width is in a range between about 20 μm to about 500 μm.

58. The process of any one of claims 53 to 57, wherein the passivation layer is not locally pre-opened using laser ablation or chemical etching.

59. The process of any one of claims 53 to 58, wherein the aluminium component further comprises silver particles or other silver source.

60. The process of any one of claims 53 to 59, wherein the heating step is a two-step process of (i) drying the paste composition, and then (ii) firing the paste composition.

61. The process of claim 60, wherein the predetermined temperature of heating step (i) is in a range of between about 250° C. to about 350° C.

62. The process of claim 60, wherein the predetermined temperature of heating step (ii) is in a range of between about 500° C. to about 1000° C.

63. The process of any one of claims 60 to 62, wherein the heating step is performed in an O₂ environment.

64. The process of any one of claims 53 to 62, wherein the passivation layer comprises SiNₓ, SiNₓH_{y}, AlOx/SiNₓ, AlOx/SiNₓH_{y}, SiO₂/AlOx/SiNₓ or SiO₂/AlOx/SiNₓH_{y} deposited on the silicon substrate.

65. The process of any one of claims 53 to 64, wherein the thickness of the silicon substrate is less that about 150 μm.

66. The process of any one of claims 53 to 65, wherein the thickness of the silicon substrate is less that about 125 μm.

67. The process of any one of claims 53 to 66, wherein the thickness of the silicon substrate is about 90 μm

68. The process of any one of claims 63 to 67, wherein the thickness of the SiNₓ or SiNₓH_{y} coating is in a range of between about 30 nm and about 200 nm.

69. The process of any one of claims 63 to 68, wherein the thickness of the AlOx is in a range of between about 2 nm and about 20 nm.

70. The process of any one of claims 53 to 69 further comprising applying a multi-wire grid to the back side of the cell, and optionally applying the multi-wire grid to the front surface of the silicon substrate, to interconnect the cells.

71. The process of claim 70, wherein the multi-wire grid comprises between about 15 and about 50 wires.

72. The process of claim 71, wherein the wires are Cu-based wires coated with a low melting-point alloy.

73. The process of any one of claims 53 to 72, wherein one or more cells are arranged to be interconnected in a series or parallel.

74. The process of claim 73, wherein the cells are encased in a module with glass, wherein the glass thickness is between about 1 mm to about 4 mm.
